(19) United States
(12) Patent Application Publication
(10) Pub. No.: US 2018/0269430 A1
(43) Pub. Date: Sep. 20, 2018

(54) ORGANIC ELECTROLUMINESCENCE DEVICE AND LIGHTING APPARATUS EQUIPPED WITH THE SAME

(71) Applicant: Konica Minolta, Inc., Tokyo (JP)

(72) Inventors: Shigeru KOJIMA, Hino-shi, Tokyo (JP); Shusaku KON, Hino-shi, Tokyo (JP); Takatoshi SUEMATSU, Nerima-ku, Tokyo (JP); Takaaki KUROKI, Hachioji-shi, Tokyo (JP)

(21) Appl. No.: 15/762,864

(22) PCT Filed: Jun. 1, 2016
(86) PCT No.: PCT/JP2016/066118

§ 371 Date: Mar. 23, 2018

(30) Foreign Application Priority Data
Sep. 30, 2015 (JP) 2015-192883

(51) Int. Cl. H01L 51/52; H01L 51/50

(52) U.S. Cl. CPC H01L 51/5275; H01L 51/5215; H01L 2251/5361; H01L 51/5234; H01L 51/5253; H01L 51/5012

(57) ABSTRACT

An object of the present invention is to provide an organic EL device having a high light transmittance and a small difference in light transmittance between a light emitting region and a non-light emitting region. An organic EL device (1) of the present invention includes a laminated body (14) in which a at least a lower transparent electrode (4), an organic functional layer (6) including a light emitting layer, an upper transparent electrode (8), a first optical adjustment layer (10), and a second optical adjustment layer (12) are laminated in this order and a sealing substrate (18) bonded to the supporting substrate (2) via an adhesive (16) so as to cover the light emitting region (L) of the light emitting layer and is characterized in that the refractive index of the first optical adjustment layer (10) is greater than the refractive index of the second optical adjustment layer (12) and the upper transparent electrode (8) and the first optical adjustment layer (10), and the first optical adjustment layer (10) and the second optical adjustment layer (12) are provided to be in direct contact with each other, respectively.

### TECHNICAL FIELD

The present invention relates to an organic electroluminescence device and a lighting apparatus equipped with the same. More particularly, it relates to an organic electroluminescence device having a high light transmittance and a small difference in light transmittance between a light emitting region and a non-light emitting region, and a lighting apparatus equipped with the same.

### BACKGROUND ART

In recent years, transparent lighting apparatuses applicable to building windows, automobile parts, display parts, and the like are demanded as a new lighting apparatus.

As electronic devices for lighting applications, organic electroluminescence (EL) devices are widely known. An organic EL device is a device which has a structure in which a light emitting layer containing a compound to emit light is sandwiched between the anode and the cathode and emits light by utilizing light emission (fluorescence/phosphorescence) generated when an exciton is generated by injecting electrons and holes into the light emitting layer and recombining them and this exciton is deactivated. The organic EL devices can emit light at a voltage of several V to several tens V, further have a wide viewing angle and high visibility since they are self-luminous type, and have attracted attention from the viewpoint of space saving, portability, and the like since they are thin film type complete solid-state devices.

For example, Patent Literature 1 discloses a technique on a double-side emission type organic EL device provided with a concavo-convex structure having a flat surface portion parallel to one surface of the organic EL device and an inclined surface portion inclined with respect to the flat surface portion for the purpose of improving the luminous efficiency and making stripes due to concave portions or convex portions less visible. However, the technique disclosed in Patent Literature 1 does not solve the degree of visual recognition due to the difference in light transmittance between the light emitting region and the non-light emitting region.

### CITATION LIST

### Patent Literature

Patent Literature 1: JP 2013-131470 A

### SUMMARY OF INVENTION

### Technical Problem

The present invention has been made in view of the above problems and circumstances, and an object thereof is to provide an organic electroluminescence device having a high light transmittance and a small difference in light transmittance between a light emitting region and a non-light emitting region, and a lighting apparatus equipped with the same.

### Solution to Problem

In the course of investigating the cause of the above-mentioned problems in order to achieve the above object, the present inventors have found out that an organic electroluminescence device having a high light transmittance and a small difference in light transmittance between the light emitting region and the non-light emitting region can be provided as it is greater than the refractive index of the first optical adjustment layer and the refractive index of the second optical adjustment layer, and the upper transparent electrode and the first optical adjustment layer, and the first optical adjustment layer and the second optical adjustment layer are provided to be in direct contact with each other, respectively, thereby completing the present invention.

In other words, the above object of the present invention can be achieved by the following means.

1. An organic electroluminescence device including:

a laminated body having at least a lower transparent electrode, an organic functional layer including a light emitting layer, an upper transparent electrode, a first optical adjustment layer, and a second optical adjustment layer laminated on a supporting substrate in this order; and

a sealing substrate pasted to the supporting substrate via an adhesive so as to cover a light emitting region of the light emitting layer; wherein

a refractive index of the first optical adjustment layer is greater than a refractive index of the second optical adjustment layer, and

the upper transparent electrode and the first optical adjustment layer, and the first optical adjustment layer and the second optical adjustment layer are provided to be in direct contact with each other, respectively.

2. The organic electroluminescence device according to Item. 1, wherein

a sealing film is provided between the second optical adjustment layer and the adhesive, and

the sealing film is provided to be in direct contact with both the second optical adjustment layer and the adhesive.

3. The organic electroluminescence device according to Item. 1 or 2, wherein the upper transparent electrode is a metal thin film.

4. The organic electroluminescence device according to any one of Items. 1 to 3, wherein a nitrogen-containing compound is contained in the first optical adjustment layer.

5. A lighting apparatus including the organic electroluminescence device according to any one of Items. 1 to 4.

### Advantageous Effects of Invention

According to the above means of the present invention, it is possible to provide an organic electroluminescence device having a high light transmittance and a small difference in light transmittance between the light emitting region and the non-light emitting region, and a lighting apparatus equipped with the same.

The manifestation mechanism and action mechanism of the effect of the present invention are not clarified, but these are presumed as follows.

The organic EL device of the present invention is characterized in that it is greater than the refractive index of the first optical adjustment layer and the refractive index of the second optical adjustment layer and the upper transparent electrode and the first optical adjustment layer, and the first optical adjustment layer and the second optical adjustment layer are provided to be in direct contact with each other, respectively. In other words, it is considered that it is possible to increase the light transmittance and to decrease the difference in light transmittance between the light emitting region and the non-light emitting region by defining the refractive index from the upper transparent electrode to the second optical adjustment layer.

### BRIEF DESCRIPTION OF DRAWINGS

FIG. 1 is a cross-sectional view illustrating a schematic configuration as an example of an organic EL device of the present invention.

FIG. 2 is a plan view illustrating a schematic configuration as an example of an organic EL device of the present invention.

FIG. 3 is a plan view illustrating a schematic configuration as an example of an organic EL device of the present invention.

FIG. 4 is a cross-sectional view illustrating a schematic configuration as an example of an organic EL device of the present invention.

FIG. 5 is a front view illustrating the outline of a vacuum ultraviolet irradiation apparatus.

### DESCRIPTION OF EMBODIMENTS

The organic EL device of the present invention includes a laminated body in which at least a lower transparent electrode, an organic functional layer including a light emitting layer, an upper transparent electrode, a first optical adjustment layer, and a second optical adjustment layer are laminated on a supporting substrate in this order and a sealing substrate pasted to the supporting substrate via an adhesive so as to cover a light emitting region of the light emitting layer and is characterized in that a refractive index of the first optical adjustment layer is greater than a refractive index of the second optical adjustment layer and the upper transparent electrode and the first optical adjustment layer, and the first optical adjustment layer and the second optical adjustment layer are provided to be in direct contact with each other, respectively. This feature is a technical feature common to the inventions according to the respective claims.

As an embodiment of the present invention, it is preferable that a sealing film is provided between the second optical adjustment layer and the adhesive and sealing film is provided to be in direct contact with both the second optical adjustment layer and the adhesive from the viewpoint of decreasing the quantity of change in light transmittance after storage.

In addition, it is preferable that the upper transparent electrode is a metal thin film from the viewpoint of decreasing damage to the organic functional layer.

In addition, it is preferable that a nitrogen-containing compound is contained in the first optical adjustment layer from the viewpoint of decreasing the quantity of change in light transmittance after storage.

In addition, the organic EL device of the present invention can be suitably used as a lighting apparatus.

Hereinafter, the present invention and its constituent elements and modes and aspects for carrying out the present invention will be described in detail. Incidentally, in the present application, the term “to” representing a numerical range is used to mean that the numerical values described before and after the term “to” are included as a lower limit value and an upper limit value.

<<Layer Configuration of Organic EL Device>>

The organic EL device of the present invention is characterized by including a laminated body in which at least a lower transparent electrode, an organic functional layer including a light emitting layer, an upper transparent electrode, a first optical adjustment layer, and a second optical adjustment layer are laminated on a supporting substrate in this order and a sealing substrate pasted to the supporting substrate via an adhesive so as to cover a light emitting region of the light emitting layer. This makes it possible to increase the light transmittance and to decrease the difference in light transmittance between the light emitting region and the non-light emitting region.

Here, the light emitting region refers to a region in which the supporting substrate, the lower transparent electrode, the organic functional layer, the upper transparent electrode, the first optical adjustment layer, the second optical adjustment layer, and the sealing substrate overlap each other when being viewed in a planar view and the non-light emitting region refers to a region in which only the supporting substrate, the lower transparent electrode (or the upper transparent electrode), the organic functional layer, the first optical adjustment layer, the second optical adjustment layer, and the sealing substrate are laminated except the upper transparent electrode (or the lower transparent electrode) among the supporting substrate, the lower transparent electrode, the organic functional layer, the upper transparent electrode, the first optical adjustment layer, the second optical adjustment layer, and the sealing substrate when being viewed in a planar view.

Hereinafter, description will be given with reference to the drawings.

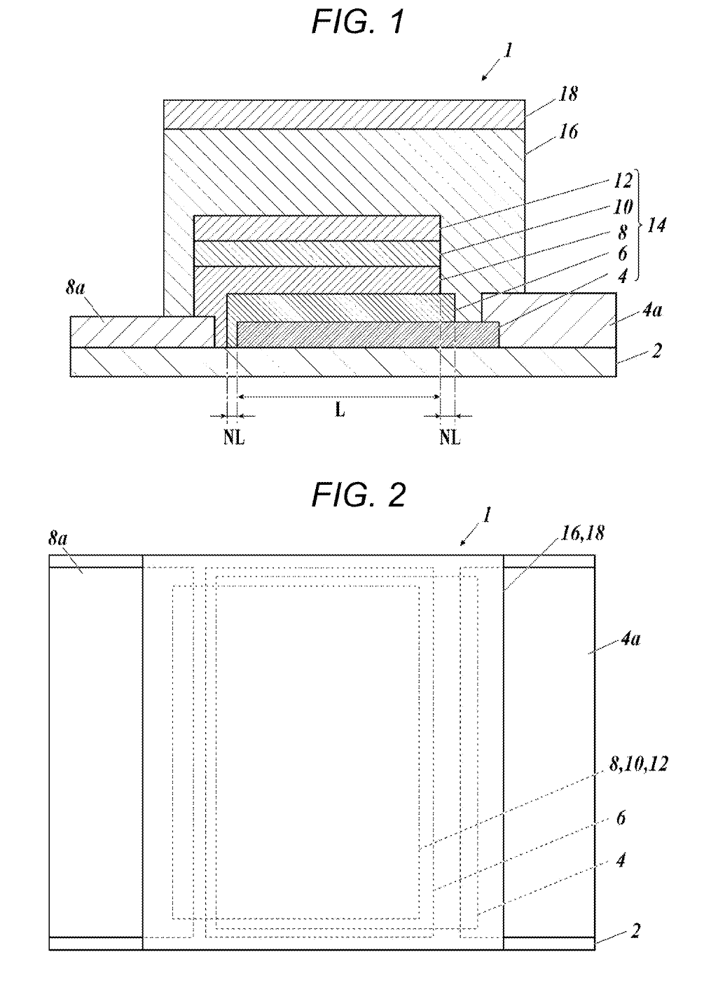

As illustrated in FIG. 1, an organic EL device 1 of the present invention has a laminated body 14 and a sealing substrate 18 bonded to the laminated body 14 via an adhesive 16 on a supporting substrate 2.

In the laminated body 14, a lower transparent electrode 4, an organic functional layer 6, an upper transparent electrode 8, a first optical adjustment layer 10, and a second optical adjustment layer 12 are laminated in this order from the supporting substrate 2 side.

At this time, the upper transparent electrode 8 and the first optical adjustment layer 10, and the first optical adjustment layer 10 and the second optical adjustment layer 12 are provided to be in direct contact with each other, respectively.

A gas barrier layer may be provided on the laminated body side of the supporting substrate 2 and/or the sealing substrate 18.

In the organic EL device illustrated in FIG. 1, a region denoted by a reference sign L is a light emitting region and a region denoted by a reference sign NL is a non-light emitting region.

In addition, as illustrated in FIG. 2, a power supply portion 4a of the lower transparent electrode 4 is provided at one end portion of the supporting substrate 2 and a power supply portion 8a of the upper transparent electrode 8 is provided at the other end portion facing the power supply portion 4a.

The sealing substrate 18 is provided so as to cover at least the light emitting region in which the lower transparent electrode 4, the organic functional layer 6, and the upper transparent electrode 8 overlap each other.

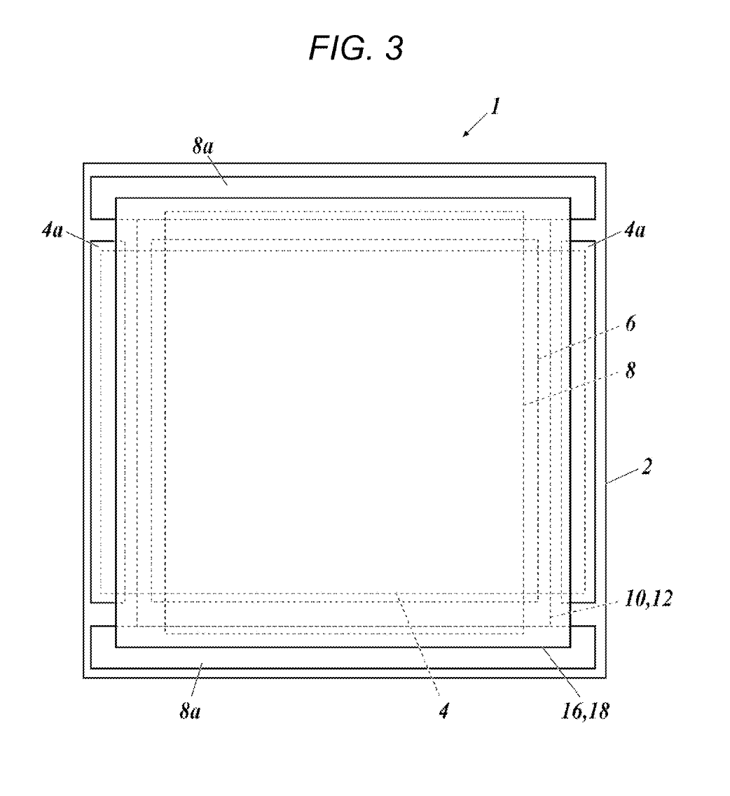

As an aspect of disposition of the power supply portion, it is also possible to provide the power supply portion 4a of the lower transparent electrode 4 at both end portions facing each other of the supporting substrate 2 and to provide the power supply portion 8a of the upper transparent electrode 8 at both end portions which are different from the above end portions and face each other as illustrated in FIG. 3 while maintaining the lamination order of the organic EL device 1 illustrated in FIG. 1.

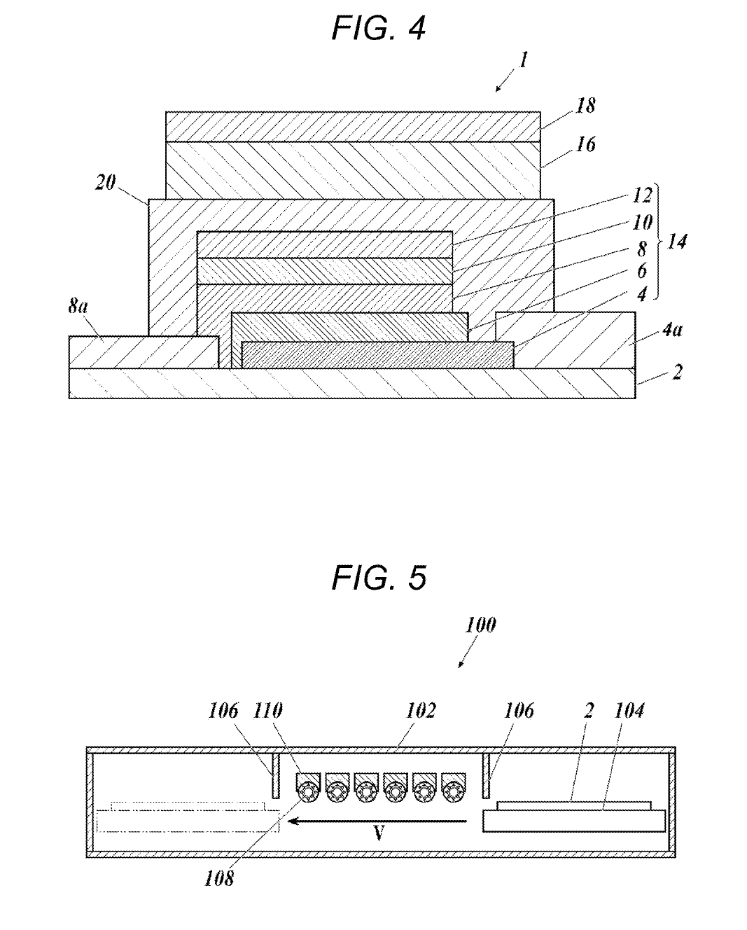

In addition, a sealing film 20 may be provided between the second optical adjustment layer 12 and the adhesive 16 in the organic EL device 1 of the present invention as illustrated in FIG. 4.

At this time, the sealing film 20 is provided to be in direct contact with both the second optical adjustment layer 12 and the adhesive 16.

Hereinafter, the respective members constituting the organic EL device of the present invention will be described.

<<Supporting Substrate (2)>>

The supporting substrate to be used in the organic EL device of the present invention is not particularly limited to the kinds such as glass and plastics, and examples thereof may preferably include glass, quartz, and a transparent resin film. A resin film capable of imparting flexibility to the organic EL device is particularly preferable.

Examples of the resin film may include films of polyesters such as polyethylene terephthalate (PET) and polyethylene naphthalate (PEN), polyethylene, polypropylene, cellophane, cellulose diacetate, cellulose triacetate (TAC), cellulose acetate butyrate, cellulose acetate propionate (CAP), cellulose esters such as cellulose acetate phthalate, and cellulose nitrate or any derivative thereof, polyvinylidene chloride, polyvinyl alcohol, polyethylene vinyl alcohol, syndiotactic polystyrene, polycarbonate, a norbornene resin, polymethyl pentene, polyether ketone, polyimide, polyether sulfone (PES), polyphenylene sulfide, polysulfones, polyether imide, polyether ketone imide, polyamide, a fluororesin, nylon, polymethyl methacrylate, acrylic or polyarylates, and cycloolefin-based resins such as ARTON (trade name, manufactured by JSR Corporation) or APEL (trade name, manufactured by Mitsui Chemicals, Inc.).

<Gas Barrier Layer>

Deterioration in the performance of the organic EL device easily occurs when a small amount of moisture or oxygen is present inside the device. Hence, it is preferable to provide a gas barrier layer which has high ability to shield moisture and oxygen in order to prevent moisture and oxygen from penetrating into the device through the supporting substrate.

It is preferable that the supporting substrate on which the gas barrier layer is formed has a water vapor transmission rate at a temperature of 25±0.5° C. and a relative humidity of 90±2% measured by a method conforming to JIS K 7129-1992 of 1×10⁻³ g/(m².24 h) or less and it is more preferable that the oxygen transmission rate measured by a method conforming to JIS K 7126-1987 is 1×10⁻³ ml/(m².24 h·atm) or less (here, 1 atm is 1.01325×10⁵ Pa) and the water vapor transmission rate at a temperature of 25±0.5° C. and a relative humidity of 90±2% is 1×10⁻³ g/(m².24 h) or less.

The composition, structure, and forming method of the gas barrier layer are not particularly limited, and a layer of an inorganic compound such as silica can be formed by a vacuum deposition or CVD method. For example, the gas barrier layer can be constituted by using a conventionally known silicon-containing polymer modified layer and a conventionally known silicon compound layer singly or in combination.

The method of forming the gas barrier layer is not particularly limited, and it is possible to use a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a laser CVD method, a thermal CVD method, a coating method, and the like, but an atmospheric pressure plasma polymerization method as described in JP 2004-68143 A is also preferable. In addition, a method of forming a gas barrier layer by coating and drying a polysilazane-containing liquid by a wet coating method, irradiating the coating film thus formed with vacuum ultraviolet light (VUV light) having a wavelength of 200 nm or less, and subjecting the coating film formed to a modification treatment is also preferable.

The thickness of the gas barrier layer is preferably in a range of from 1 to 500 nm and more preferably in a range of from 10 to 300 nm. It is possible to exert desired gas barrier performance when the thickness of the gas barrier layer is 1 nm or more and it is possible to prevent deterioration in the film quality such as cracking of the dense silicon oxynitride film when the thickness is 500 nm or less.

<Antistatic Layer>

In the organic EL device of the present invention, an antistatic layer may be provided on one surface of the supporting substrate. The antistatic layer is constituted by an antistatic agent and a binder resin for holding the antistatic agent.

It is preferable that the antistatic layer contains an organic antistatic agent as the antistatic agent.

As the organic antistatic agent, it is preferable to contain one or more kinds selected from a conjugated polymer or an ionic polymer. In addition, the antistatic layer may be constituted to contain another conductive polymer and another antistatic agent.

In the antistatic layer, it is preferable not to contain metal oxide particles which are likely to be desorbed at the time of lamination as an antistatic agent. Hence, the content of the metal oxide particles with respect to the entire mass of the antistatic layer is preferably 5% by mass or less and more preferably 2% by mass or less, and a configuration not containing metal oxide particles is particularly preferable. Examples of the metal oxide particles which are preferably not contained in the antistatic layer may include ZnO, TiO₂, SnO₂, Al₂O₃, In₂O₃, MgO, BaO, MoO₂, and V₂O₅ or any composite oxide thereof. However, SiO₂ is excluded from the definition of metal oxide particles which are preferably not contained in the antistatic layer.

(Organic Antistatic Agent)

The organic antistatic agent is basically constituted by an organic material exhibiting antistatic ability. The organic antistatic agent is a material which can decrease the sheet resistance value on the back side of the antistatic layer to 1×10¹¹ Ω/sq. or less, preferably 1×10¹⁰ Ω/sq. or less, and more preferably 1×10⁹ Ω/sq. or less when forming the antistatic layer.

Examples of the organic antistatic agent may include a conventionally known surfactant type antistatic agent, a silicone-based antistatic agent, an organic boric acid-based antistatic agent, a polymer-based antistatic agent, and an antistatic polymer material. In particular, it is preferable to use an ionic conductive substance and the like as the organic antistatic agent from the viewpoint of preventing static charge of the antistatic layer. The ionic conductive substance is a substance containing an ion exhibiting electrical conductivity. Examples of the ionic conductive substance may include a conjugated polymer and an ionic polymer.

(Conjugated Polymer)

Examples of the conjugated polymer may include a π-electron conductive polymer composite of a polymer having the following (1) to (8) in a side chain via a connecting group.

(1) Aliphatic conjugated system: a polymer that is alternately and continuously linked by a carbon-carbon conjugated system such as polyacetylene, for example, polyacetylene and poly (1,6-heptadiene)

(2) Aromatic conjugated system: a polymer having developed conjugation in which aromatic hydrocarbons are continuously bonded to each other such as poly(p-phenylene), for example, polyparaphenylene, polynaphthalene, and polyanthracene

(3) Heterocyclic conjugated system: a polymer having a developed conjugated system by bonding of a heterocyclic compound such as polypyrrole and polythiophene, for example, polypyrrole and any derivative thereof, polyfuran and any derivative thereof, polythiophene and any derivative thereof, polyisothionaphthene and any derivative thereof, and polyselenophene and any derivative thereof

(4) Heteroatom-containing conjugated system: a polymer in which aliphatic or aromatic conjugated systems are bonded to each other by a hetero atom such as polyaniline, for example, polyaniline and any derivative thereof, poly (p-phenylene sulfide) and any derivative thereof, poly (p-phenylene oxide) and any derivative thereof, and poly (p-phenylene selenide) and any derivative thereof and poly(vinylene sulfide), poly (vinylene oxide), and poly (vinylene selenide) for an aliphatic system

(5) Mixed type conjugated system: a conjugated polymer having a structure in which the constitutional units of the conjugated systems are alternately bonded to each other such as poly(phenylene vinylene), for example, poly (p-phenylene vinylene) and any derivative thereof, poly(pyrrole vinylene) and any derivative thereof, poly(thiophene vinylene) and any derivative thereof, poly(furan vinylene) and any derivative thereof, and poly(2,2′-thienylpyrrole) any derivative thereof

(6) Multiple-chain type conjugated system: a conjugated system having a plurality of conjugated chains in the molecule and a polymer having a structure close to an aromatic conjugated system, for example, poly-peri-naphthalene

(7) Metal phthalocyanine system: metal phthalocyanines or polymers in which these molecules are bonded by a hetero atom or a conjugated system, for example, metal phthalocyanine

(8) Conductive composite: a polymer obtained by graft copolymerizing the conjugated polymer chain with a saturated polymer and a composite obtained by polymerizing the conjugated polymer in a saturated polymer, for example, polythiophene (including derivatives) and polypyrrole (including derivatives) of (3), polyaniline (including derivatives) of (4), and poly (p-phenylene vinylene) (including any derivative thereof) and poly(thiophene vinylene) (including any derivative thereof) of (5)

(Ionic Polymer)

Examples of the ionic polymer may include the following (1) to (3).

(1) Anionic polymer compounds as found in JP 49-23828 B, JP 49-23827 B, JP 47-28937 B, and the like

(2) Ionene type polymers having a dissociable group in the main chain as found in JP 55-734 B, JP 50-54672 A, JP 59-14735 B, JP 57-18175 B, JP 57-18176 B, JP 57-56059 B, and the like

(3) Cationic pendant type polymers having a cationic dissociable group in the side chain as found in JP 53-13223 B, JP 57-15376 B, JP 53-45231 B, JP 55-145783 B, JP 55-65950 B, JP 55-67746 B, JP 57-11342 B, JP 57-19735 B, JP 58-56858 B, JP 61-27853 A, JP 62-9346 B, and the like

(Conductive Polymer)

Examples of the conductive polymer constituting the antistatic layer may include the ionene conductive polymer described in JP 9-203810 A or a quaternary ammonium cation conductive polymer having intermolecular crosslinking.

(Other Antistatic Agents)

As other antistatic agents constituting the antistatic layer, for example, it is possible to use antistatic hard coat agents described in JP 2006-265271 A, JP 2007-70456 A, JP 2009-62406 A, and the like. In addition, it is possible to appropriately select and to use, for example, antistatic agents which are manufactured by Aica Kogyo Co., Ltd. and obtained as commercially available products as well.

(Binder Resin)

As the binder resin for holding the antistatic agent in the antistatic layer, for example, it is possible to use a cellulose derivative such as cellulose diacetate, cellulose triacetate, cellulose acetate butyrate, cellulose acetate phthalate, or cellulose nitrate, a polyester such as polyvinyl acetate, polystyrene, polycarbonate, polybutylene terephthalate, or copolybutylene/tere/isophthalate, polyvinyl alcohol, a polyvinyl alcohol derivative such as polyvinyl formal, polyvinyl acetal, polyvinyl butyral, or polyvinyl benzal, a norbornene-based polymer containing a norbornene compound, an acrylic resin such as polymethyl methacrylate, polyethyl methacrylate, polypropylthyl methacrylate, polybutyl methacrylate, or polymethyl acrylate, and a copolymer of an acrylic resin and another resin. In particular, a cellulose derivative and an acrylic resin are preferable, and an acrylic resin is most preferably used.

As the binder resin to be used in the antistatic layer, a thermoplastic resin having a weight average molecular weight of 400,000 or more and a glass transition temperature in a range of from 80° C. to 110° C. is preferable. The glass transition temperature can be determined by the method described in JIS K 7121. The binder resin to be used here is 60% by mass or more and more preferably 80% by mass or more of the entire resin mass constituting the antistatic agent layer, and an actinic ray-curable resin or a thermosetting resin can also be applied if necessary.

<<Laminated Body (14)>>

The laminated body according to the present invention is constituted by laminating at least a lower transparent electrode, an organic functional layer, an upper transparent electrode, a first optical adjustment layer, and a second optical adjustment layer on a supporting substrate in this order.

<Upper Transparent Electrode (8) and Lower Transparent Electrode (4)>

The upper transparent electrode and the lower transparent electrode according to the present invention function as an anode or a cathode. For example, the lower transparent electrode functions as an anode when the upper transparent electrode functions as a cathode.

Incidentally, transparency in the upper transparent electrode and the lower transparent electrode means that the light transmittance at a wavelength of 550 nm is 50% or more.

It is preferable that the upper transparent electrode is a thin film metal, and it is more preferable that both the upper transparent electrode and the lower transparent electrode are thin film metals.

(Anode)

As the anode, those using a metal, an alloy, an electrically conductive compound, or a mixture thereof having a great work function (4 eV or more and preferably 4.5 eV or more) as an electrode substance are preferably used. Specific examples of such an electrode substance may include conductive transparent materials such as metals such as Au and Ag, indium-tin oxide (ITO), SnO₂, ZnO, GZO (Ga-doped ZnO), AZO (Al-doped ZnO), antimony-doped zinc oxide, ATO (Sb-doped SnO), IZO (In₂O₃—ZnO), and IGZO (indium-gallium-zinc oxide).

As the anode, a thin film of these electrode substances may be formed by a method such as vapor deposition or sputtering and a pattern of a desired shape may be formed by a photolithography method or a pattern may be formed via a mask having a desired shape at the time of vapor deposition or sputtering of the electrode substance in a case in which the precision of pattern is not much required (about 100 μm or more).

Alternatively, it is also possible to use a wet film forming method such as a printing method or a coating method in the case of using a coatable substance such as an organic conductive compound. In a case in which light emission is taken out from this anode, it is desirable to set the transmittance to be greater than 10% and the sheet resistance as the anode is preferably several hundreds Ω/□ or less.

The film thickness of anode is usually selected in a range of from 10 nm to 1 μm and preferably from 10 to 200 nm although it also depends on the material.

The anode is preferably a metal oxide from the viewpoint of improving the light transmittance. Such a metal oxide is not particularly limited, but examples thereof may include indium-tin oxide (ITO), SnO₂, ZnO, GZO (Ga-doped ZnO), AZO (Al-doped ZnO), antimony-doped zinc oxide, ATO (Sb-doped SnO), IZO (In₂O₃—ZnO), and IGZO (indium-gallium-zinc oxide).

(Cathode)

As the cathode, those using a metal (referred to as an electron-injecting metal), an alloy, an electrically conductive compound, or a mixture thereof having a small work function (4 eV or less) as an electrode substance are used. Specific examples of such an electrode substance may include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, aluminum, and a rare earth metal. Among these, a mixture of an electron-injecting metal and a second metal of a metal which has a greater work function value and is more stable than this, for example, a magnesium/silver mixture, a magnesium/aluminum mixture, a magnesium/indium mixture, an aluminum/aluminum oxide (Al₂O₃), a lithium/aluminum mixture, and aluminum are suitable from the viewpoint of electron injecting property and durability to oxidation and the like.

The cathode can be fabricated by forming a thin film of these electrode substances by a method such as vapor deposition or sputtering. In addition, the sheet resistance as the cathode is preferably several hundreds Ω/□ or less. The film thickness is usually selected in a range of from 10 nm to 5 μm and preferably from 50 to 200 nm.

In addition, a transparent or translucent cathode can be fabricated by fabricating the above metal as the cathode in a film thickness of from 1 to 20 nm and then fabricating the conductive transparent material mentioned in the description of the anode thereon, and it is possible to fabricate a device in which both the anode and the cathode exhibit transparency by applying this.

It is preferable that the cathode is provided as a thin film of a metal capable of being vapor deposited from the viewpoint of not damaging the organic functional layer. Among them, silver is preferable since the transmittance per unit film thickness is high.

The cathode may be constituted by silver only or an alloy containing silver. Examples of such an alloy may include silver-magnesium (Ag—Mg), silver-copper (Ag—Cu), silver-palladium (Ag—Pd), silver-palladium-copper (Ag—Pd—Cu), and silver-indium (Ag—In).

Such a cathode may have a configuration in which a layer constituted by silver (or an alloy containing silver) is laminated in plural layers if necessary.

In addition, the cathode to be constituted by silver (or an alloy containing silver) preferably has a film thickness in a range of from 5 to 15 nm. It is more preferable that the film thickness is thinner than 15 nm since the absorbing component or reflecting component of the layer decreases and the transmittance of the transparent electrode is improved. In addition, it is preferable the film thickness is thicker than 5 nm since the conductivity of the layer is sufficient.

In addition, it is preferable to provide a layer of Al, Ca, Li, or the like between the silver electrode and the electron injecting layer in order to decrease the driving voltage in the case of using silver as the cathode material. Among these, Ca and Li are more preferable from the viewpoint of improving the light transmittance.

<Organic Functional Layer>

Examples of a representative configuration of the organic functional layer according to the present invention may include the following configurations, but the configuration is not limited thereto.

(1) (Anode)/light emitting layer/(cathode)

(2) (Anode)/light emitting layer/electron transporting layer/(cathode)

(3) (Anode)/hole transporting layer/light emitting layer/(cathode)

(4) (Anode)/hole transporting layer/light emitting layer/electron transporting layer/(cathode)

(5) (Anode)/hole transporting layer/light emitting layer/electron transporting layer/electron injecting layer/(cathode)

(6) (Anode)/hole injecting layer/hole transporting layer/light emitting layer/electron transporting layer/(cathode)

(7) (Anode)/hole injecting layer/hole transporting layer/(electron blocking layer/) light emitting layer/(hole blocking layer/) electron transporting layer/electron injecting layer/(cathode)

Among the above, the configuration of (7) is preferable, but the configuration is not particularly limited.

The light emitting layer according to the present invention may be constituted by plural layers, and in this case, a non-light emitting intermediate layer may be provided between the respective light emitting layers.

<Light Emitting Layer>

The light emitting layer according to the present invention is a layer which emits light by recombination of electrons and holes to be injected from the electrodes or the electron transporting layer and the hole transporting layer.

The sum of the thicknesses of the light emitting layers is not particularly limited, but it is preferably adjusted to be in a range of from 2 nm to 5 μm, still more preferably adjusted to be in a range of from 2 to 200 nm, and particularly preferably adjusted to be in a range of from 5 to 100 nm from the viewpoint of homogeneity of the film and of preventing the application of an unrequired high voltage at the time of light emission and improving the stability of luminescent color with respect to the driving current.

In addition, the thickness of each light emitting layer is preferably adjusted to be in a range of from 2 nm to 1 μm, more preferably adjusted to be in a range of from 2 to 200 nm, and still more preferably adjusted to be in a range of from 3 to 150 nm.

It is preferable that the light emitting layer contains a light emitting dopant (also referred to as a luminescent dopant compound, a dopant compound, or simply a dopant) and a host compound (also referred to as a matrix material, a light emitting host compound, or simply a host).

(Light Emitting Dopant)

As the light emitting dopant, a fluorescent light emitting dopant (also referred to as a fluorescent dopant or a fluorescent compound) and a phosphorescent light emitting dopant (also referred to as a phosphorescent dopant or a phosphorescent compound) are preferably used. In the present invention, it is preferable that at least one light emitting layer contains a phosphorescent light emitting dopant.

The concentration of light emitting dopant in the light emitting layer can be arbitrarily determined based on the particular dopant to be used and the requirements of the device, and the light emitting dopant may be contained at a uniform concentration in the film thickness direction of the light emitting layer or may have an arbitrary concentration distribution.

In addition, as the light emitting dopant according to the present invention, plural kinds may be used concurrently or a combination of dopants having different structures or a combination of a fluorescent light emitting dopant and a phosphorescent light emitting dopant may be used. This makes it possible to obtain an arbitrary luminescent color.

(Phosphorescent Light Emitting Dopant)

The phosphorescent light emitting dopant according to the present invention is a compound from which light emission due to the excited triplet is observed, specifically, it is a compound which emits phosphorescence at room temperature (25° C.), and it is defined as a compound having a phosphorescent quantum yield of 0.01 or more at 25° C., but a preferable phosphorescent quantum yield is 0.1 or more.

The phosphorescent quantum yield can be measured by the method described in the spectroscopy II of the fourth edition of Experimental Chemistry Course 7, page 398 (1992 edition, Maruzen). The phosphorescent quantum yield in a solution can be measured by using various solvents, but the phosphorescent light emitting dopant according to the present invention may be one that achieves the phosphorescent quantum yield (0.01 or more) in any of arbitrary solvents.

There are two kinds of the principle of light emission from the phosphorescent light emitting dopant, and one is an energy transfer type in which an excited state of the host compound is generated as the recombination of carriers occurs on the host compound to which the carriers are transported and light emission is obtained from the phosphorescent light emitting dopant as this energy is transferred to the phosphorescent light emitting dopant. The other one is a carrier trap type in which the phosphorescent light emitting dopant becomes a carrier trap and light emission is obtained from the phosphorescent light emitting dopant as the recombination of carriers occurs on the phosphorescent light emitting dopant.

In either case, it is a condition that the energy of the excited state of the phosphorescent light emitting dopant is lower than the energy of the excited state of the host compound.

The phosphorescent light emitting dopant which can be used in the present invention can be appropriately selected from known ones to be used in the light emitting layer of an organic EL device and used.

Specific examples of known phosphorescent dopants that can be used in the present invention may include the compounds described in the following literatures.

The literatures are, for example, Nature 395, 151 (1998), Appl. Phys. Lett. 78, 1622 (2001), Adv. Mater. 19, 739 (2007), Chem. Mater. 17, 3532 (2005), Adv. Mater. 17, 1059 (2005), WO 2009/100991 A, WO 2008/101842 A, WO 2003/040257 A, US 2006/835469, US 2006/0202194, US 2007/0087321, US 2005/0244673, Inorg. Chem. 40, 1704 (2001), Chem. Mater. 16, 2480 (2004), Adv. Mater. 16, 2003 (2004), Angew. Chem. Int. Ed. 2006, 45, 7800, Appl. Phys. Lett. 86, 153505 (2005), Chem. Lett. 34, 592 (2005), Chem. Commun. 2906 (2005), Inorg. Chem. 42, 1248 (2003), WO 2009/050290 A, WO 2002/015645 A, WO 2009/000673 A, US 2002/0034656, U.S. Pat. No. 7,332,232, US 2009/0108737, US 2009/0039776, U.S. Pat. No. 6,921,915, U.S. Pat. No. 6,687,266, US 2007/0190359, US 2006/0008670, US 2009/0165846, US 2008/0015355, U.S. Pat. No. 7,250,226, U.S. Pat. No. 7,396,598, US 2006/0263635, US 2003/0138657, US 2003/0152802, U.S. Pat. No. 7,090,928, Angew. Chem. Int. Ed. 47, 1 (2008), Chem. Mater. 18, 5119 (2006), Inorg. Chem. 46, 4308 (2007), Organometallics 23, 3745 (2004), Appl. Phys. Lett. 74, 1361 (1999), WO 2002/002714 A, WO 2006/009024 A, WO 2006/056418 A, WO 2005/019373 A, WO 2005/123873 A, WO 2007/004380 A, WO 2006/082742 A, US 2006/0251923, US 2005/0260441, U.S. Pat. No. 7,393,599, U.S. Pat. No. 7,534,505, U.S. Pat. No. 7,445,855, US 2007/0190359, US 2008/0297033, U.S. Pat. No. 7,338,722, US 2002/0134984, U.S. Pat. No. 7,279,704, US 2006/098120, US 2006/103874, WO 2005/076380 A, WO 2010/032663 A, WO 2008/140115 A, WO 2007/052431 A, WO 2011/134013 A, WO 2011/157339 A, WO 2010/086089 A, WO 2009/113646 A, WO 2012/020327 A, WO 2011/051404 A, WO 2011/004639 A, WO 2011/073149 A, US 2012/228583, US 2012/212,126, JP 2012-069737 A, JP 2012-195554 A, JP 2009-114086 A, JP 2003-81988 A, JP-2002-302671 A, JP 2002-363552 A, JP 2009-231516 A, WO 2012/112853 A, JP 5124942 B1, JP 4784600 B1, and JP 2010-47764 A.

Among these, as the phosphorescent light emitting dopant, an organometallic complex having Ir as the central metal can be mentioned. Still more preferably, a complex having at least one coordination mode of a metal-carbon bond, a metal-nitrogen bond, a metal-oxygen bond, or a metal-sulfur bond is preferable.

(Fluorescent Light Emitting Dopant)

The fluorescent light emitting dopant (hereinafter also referred to as a fluorescent dopant) will be described.

The fluorescent dopant is a compound capable of emitting light due to the excited singlet, and it is not particularly limited as long as light emission due to the singlet excited is observed.

Examples of the fluorescent dopant may include an anthracene derivative, a pyrene derivative, a chrysene derivative, a fluoranthene derivative, a perylene derivative, a fluorene derivative, an arylacetylene derivative, a styrylarylene derivative, a styrylamine derivative, an arylamine derivative, a boron complex, a coumarin derivative, a pyran derivative, a cyanine derivative, a croconium derivative, a squarylium derivative, an oxobenzanthracene derivative, a fluorescein derivative, a rhodamine derivative, a pyrylium derivative, a perylene derivative, a polythiophene derivative, or a rare earth complex-based compound.

In recent years, light emitting dopants utilizing delayed fluorescence have also been developed, and these may be used.

Specific examples of the light emitting dopants utilizing delayed fluorescence may include the compounds described in, for example, WO 2011/156793 A, JP 2011-213643 A, and JP 2010-93181 A, but the present invention is not limited thereto.

(Host Compound)

The host compound according to the present invention is a compound which is mainly responsible for injection and transport of charges in the light emitting layer, and light emission from the host compound itself is not substantially observed in the organic EL device.

The host compound is preferably a compound having a phosphorescent quantum yield of phosphorescence at room temperature (25° C.) of less than 0.1 and still more preferably a compound having a phosphorescent quantum yield of less than 0.01.

In addition, the mass ratio of the host compound in the light emitting layer is preferably 20% or more among the compounds contained in the layer.

In addition, the excited state energy of the host compound is preferably higher than the excited state energy of the phosphorescent light emitting dopant contained in the same layer.

The host compound may be used singly or plural kinds thereof may be used concurrently. By using plural kinds of host compounds, it is possible to adjust the transfer of charges and to improve the efficiency of the organic EL device.

The host compound which can be used in the present invention is not particularly limited, and a compound to be conventionally used in an organic EL device can be used. The host compound may be a low molecular weight compound or a polymer compound having a repeating unit, or it may be a compound having a reactive group such as a vinyl group or an epoxy group.

From the viewpoint of having a hole transporting ability or an electron transporting ability, preventing an increase in the wavelength for light emission, and further stably operating the organic EL device with respect to heat generation during high temperature driving or device driving, it is preferable that a known host compound has a high glass transition temperature (Tg). The Tg is preferably 90° C. or higher and more preferably 120° C. or higher.

Here, the glass transition temperature (Tg) is a value determined by a method conforming to JIS K 7121 using DSC (Differential Scanning Calorimetry).

Specific examples of known host compounds to be used in the organic EL device of the present invention may include the compounds described in the following literatures, but the present invention is not limited thereto.

The literatures are JP 2001-257076 A, JP 2002-308855 A, JP 2001-313179 A, JP 2002-319491 A, JP 2001-357977 A, JP 2002-334786 A, JP 2002-8860 A, JP 2002-334787 A, JP 2002-15871 A, JP 2002-334788 A, JP 2002-43056 A, JP 2002-334789 A, JP 2002-75645 A, JP 2002-338579 A, JP 2002-105445 A, JP 2002-343568 A, JP 2002-141173 A, JP 2002-352957 A, JP 2002-203683 A, JP 2002-363227 A, JP 2002-231453 A, JP 2003-3165 A, JP 2002-234888 A, JP 2003-27048 A, JP 2002-255934 A, JP 2002-260861 A, JP 2002-280183 A, JP 2002-299060 A, JP 2002-302516 A, JP 2002-305083 A, JP 2002-305084 A, JP 2002-308837 A, US 2003/0175553, US 2006/0280965, US 2005/0112407, US 2009/0017330, US 2009/0030202, US 2005/0238919, WO 2001/039234 A, WO 2009/021126 A, WO 2008/056746 A, WO 2004/093207 A, WO 2005/089025 A, WO 2007/063796 A, WO 2007/063754 A, WO 2004/107822 A, WO 2005/030900 A, WO 2006/114966 A, WO 2009/086028 A, WO 2009/003898 A, WO 2012/023947 A, JP 2008-074939 A, JP 2007-254297 A, EP 2034538 B, and the like.

<Hole Transporting Layer>

The hole transporting layer in the present invention is composed of a material having a function to transport holes, and it may have a function to transmit the holes injected from the anode to the light emitting layer.

The total thickness of the hole transporting layer is not particularly limited, but it is usually in a range of from 5 nm to 5 μm, more preferably in a range of from 2 to 500 nm, and still more preferably in a range of from 5 to 200 nm.

The material to be used in the hole transporting layer (hereinafter referred to as a hole transporting material) may exhibit any of hole injecting property, hole transporting property, or electron barrier property, and an arbitrary material can be selected from among conventionally known compounds and used.

Examples thereof may include a porphyrin derivative, a phthalocyanine derivative, an oxazole derivative, an oxadiazole derivative, a triazole derivative, an imidazole derivative, a pyrazoline derivative, a pyrazolone derivative, a phenylenediamine derivative, a hydrazone derivative, a stilbene derivative, a polyarylalkane derivative, a triarylamine derivative, a carbazole derivative, an indolocarbazole derivative, an isoindole derivative, an acene derivative such as anthracene or naphthalene, a fluorene derivative, a fluorenone derivative, and polyvinylcarbazole, a polymer material or oligomer in which an aromatic amine is introduced into the main chain or a side chain, polysilane, and a conductive polymer or oligomer (for example, PEDOT:PSS, an aniline-based copolymer, polyaniline, or polythiophene).

Examples of the triarylamine derivative may include a benzidine type typified by α-NPD, a starburst type typified by MTDATA, and a compound having fluorene or anthracene at the triarylamine coupling core moiety.

In addition, a hexaazatriphenylene derivative as described in JP 2003-519432 W and JP 2006-135145 A can also be used as a hole transporting material in the same manner.

Furthermore, it is also possible to use a hole transporting layer which is doped with impurities and exhibits high p-property. Examples thereof may include those described in JP 4-297076 A, JP 2000-196140 A, JP 2001-102175 A, J. Appl. Phys., 95, 5773 (2004), and the like.

In addition, it is also possible to use a so-called p-type hole transporting material or an inorganic compound such as p-type-Si or p-type-SiC as described in JP 11-251067 A and a literature written by J. Huang et. al. (Applied Physics Letters 80 (2002), p. 139). Furthermore, an ortho-metalated organometallic complex which has Ir or Pt as the central metal and is typified by Ir(ppy)3 is also preferably used.

As the hole transporting material, those described above can be used, but a triarylamine derivative, a carbazole derivative, an indolocarbazole derivative, an azatriphenylene derivative, an organometallic complex, a polymer material or oligomer in which an aromatic amine is introduced into the main chain or a side chain, and the like are preferably used.

Specific examples of known preferable hole transporting materials to be used in the organic EL device of the present invention may include the compounds described in the following literatures in addition to the literatures described above, but the present invention is limited thereto.

The literatures are, for example, Appl. Phys. Lett. 69, 2160 (1996), J. Lumin. 72-74, 985 (1997), Appl. Phys. Lett. 78, 673 (2001), Appl. Phys. Lett. 90, 183503 (2007), Appl. Phys. Lett. 90, 183503 (2007), Appl. Phys. Lett. 51, 913 (1987), Synth. Met. 87, 171 (1997), Synth. Met. 91, 209 (1997), Synth. Met. 111, 421 (2000), SID Symposium Digest, 37, 923 (2006), J. Mater. Chem. 3, 319 (1993), Adv. Mater. 6, 677 (1994), Chem. Mater. 15, 3148 (2003), US 2003/0162053, US 2002/0158242, US 2006/0240279, US 2008/0220265, U.S. Pat. No. 5,061,569, WO 2007/002683 A, WO 2009/018009 A, EP 650 955 B, US 2008/0124572, US 2007/0278938, US 2008/0106190, US 2008/0018221, WO 2012/115034 A, JP 2003-519432 W, JP 2006-135145 A, and US 2013/0049576.

The hole transporting material may be used singly or plural kinds thereof may be used concurrently.

<Electron Blocking Layer>

The electron blocking layer is a layer having a function of a hole transporting layer in a broad sense, preferably it is composed of a material having a low ability to transport electrons while having a function to transport holes, and it is possible to improve the recombination probability of electrons and holes by blocking electrons while transporting holes.

In addition, the configuration of the hole transporting layer described above can be used as the electron blocking layer if necessary.

The electron blocking layer is preferably provided to be adjacent to the anode side of the light emitting layer.

The thickness of the electron blocking layer is preferably in a range of from 3 to 100 nm and still more preferably in a range of from 5 to 30 nm.

As the material to be used in the electron blocking layer, the material to be used in the hole transporting layer described above is preferably used and the material to be used as the host compound described above is also preferably used in the electron blocking layer.

<Hole Injecting Layer>

A hole injecting layer (also referred to as an anode buffer layer) is a layer to be provided between the anode and the light emitting layer in order to lower the driving voltage and to improve the intensity of light emission, and it is described in detail in Part 2, Chapter 2 “Electrode Materials” (pages 123 to 166) of “Organic EL Devices and Their Frontier of Industrialization (Nov. 30, 1998 issued by NTS Co., Ltd.)”.

In the present invention, the hole injecting layer may be provided if necessary and present between the anode and the light emitting layer or between the anode and the hole transporting layer as described above.

The hole injecting layer is also described in JP 9-45479 A, JP 9-260062 A, and JP 8-288069 A in detail, and examples of a material to be used in the hole injecting layer may include materials to be used in the hole transporting layer described above.

Among them, a phthalocyanine derivative typified by copper phthalocyanine, a hexaazatriphenylene derivative as described in JP 2003-519432 W, JP 2006-135145 A, and the like, a metal oxide typified by vanadium oxide, amorphous carbon, a conductive polymer such as polyaniline (emeraldine) or polythiophene, an ortho-metalated complex typified by tris(2-phenylpyridine) iridium complex and the like, a triarylamine derivative, and the like are preferable.

The materials to be used in the hole injecting layer described above may be used singly or plural kinds thereof may be used concurrently.

<Electron Transporting Layer>

The electron transporting layer in the present invention is composed of a material having a function to transport electrons, and it may have a function to transmit electrons injected from the cathode to the light emitting layer.

The total thickness of the electron transporting layer of the present invention is not particularly limited, but it is usually in a range of from 2 nm to 5 μm, more preferably in a range of from 2 to 500 nm, and still more preferably in a range of from 5 to 200 nm.

Meanwhile, the voltage is likely to increase when the thickness of the electron transporting layer is increased, and thus the electron mobility in the electron transporting layer is preferably 1×10⁻⁵ cm²/Vs or more particularly in a case in which the thickness is thick.

The material to be used in the electron transporting layer (hereinafter referred to as an electron transporting material) may exhibit any of electron injecting property, electron transporting property, or hole barrier property, and an arbitrary material can be selected from among conventionally known compounds and used.

Examples thereof may include a nitrogen-containing aromatic heterocyclic derivative (a carbazole derivative, an azacarbazole derivative (one in which one or more carbon atoms constituting the carbazole ring are substituted with a nitrogen atom), a pyridine derivative, a pyrimidine derivative, a pyrazine derivative, a pyridazine derivative, a triazine derivative, a quinoline derivative, a quinoxaline derivative, a phenanthroline derivative, an azatriphenylene derivative, an oxazole derivative, a thiazole derivative, an oxadiazole derivative, a thiadiazole derivative, a triazole derivative, a benzimidazole derivative, a benzoxazole derivative, a benzthiazole derivative, or the like), a dibenzofuran derivative, a dibenzothiophene derivative, a silole derivative, and an aromatic hydrocarbon ring derivative (a naphthalene derivative, an anthracene derivative, a triphenylene, or the like).

In addition, it is also possible to use a metal complex having a quinolinol skeleton or a dibenzoquinolinol skeleton as a ligand, for example, tris(8-quinolinol)aluminum (Alq₃), tris(5,7-dichloro-8-quinolinol)aluminum, tris(5,7-dibromo-8-quinolinol)aluminum, tris(2-methyl-8-quinolinol)aluminum, tris(5-methyl-8-quinolinol)aluminum, bis(8-quinolinol)zinc (Znq), and the like and metal complexes in which the central metal of these metal complexes is substituted with In, Mg, Cu, Ca, Sn, Ga, or Pb as the electron transporting material.

In addition to these, it is also possible to preferably use a metal free or metal phthalocyanine or those in which the terminals of these are substituted with an alkyl group, a sulfonic acid group, or the like as the electron transporting material. In addition, a distyrylpyrazine derivative which is also used as a material of the light emitting layer can be used as the electron transporting material, and an inorganic semiconductor such as n-type-Si or n-type-SiC can also be used as the electron transporting material in the same manner as in the hole injecting layer and the hole transporting layer.

In addition, it is also possible to use a polymer material having these materials introduced into the polymer chain or using these materials as the main chain of the polymer.

In the electron transporting layer, the electron transporting layer may be doped with a doping material as a guest material to form an electron transporting layer exhibiting high n-property (electron rich). Examples of the doping material may include an n-type dopant such as a metal compound such as a metal complex or a metal halide. Specific examples of the electron transporting layer having such a configuration may include those described in the literatures, for example, JP 4-297076 A, JP 10-270172 A, JP 2000-196140 A, JP 2001-102175 A, and J. Appl. Phys., 95, 5773 (2004).

In addition, it is preferable that a metal fluoride is doped from the viewpoint of lowering the driving voltage.

Specific examples of known preferable electron transporting materials to be used in the organic EL device of the present invention may include the compounds described in the following literatures, but the present invention is not limited thereto.

The literatures are U.S. Pat. No. 6,528,187, U.S. Pat. No. 7,230,107, US 2005/0025993, US 2004/0036077, US 2009/0115316, US 2009/0101870, US 2009/0179554, WO 2003/060956 A, WO 2008/132085 A, Appl. Phys. Lett. 75, 4 (1999), Appl. Phys. Lett. 79, 449 (2001), Appl. Phys. Lett. 81, 162 (2002), Appl. Phys. Lett. 81, 162 (2002), Appl. Phys. Lett. 79, 156 (2001), U.S. Pat. No. 7,964,293, US 2009/030202, WO 2004/080975 A, WO 2004/063159 A, WO 2005/085387 A, WO 2006/067931 A, WO 2007/086552 A, WO 2008/114690 A, WO 2009/069442 A, WO 2009/066779 A, WO 2009/054253 A, WO 2011/086935 A, WO 2010/150593 A, WO 2010/047707 A, EP 2311826 B, JP 2010-251675 A, JP 2009-209133 A, JP 2009-124114 A, JP 2008-277810 A, JP 2006-156445 A, JP 2005-340122 A, JP 2003-45662 A, JP 2003-31367 A, JP 2003-282270 A, WO 2012/115034 A, and the like.

More preferred examples of the electron transporting material may include a pyridine derivative, a pyrimidine derivative, a pyrazine derivative, a triazine derivative, a dibenzofuran derivative, a dibenzothiophene derivative, a carbazole derivative, an azacarbazole derivative, and a benzimidazole derivative.

The electron transporting material may be used singly or plural kinds thereof may be used concurrently.

<Hole Blocking Layer>

The hole blocking layer is a layer having a function of an electron transporting layer in a broad sense, preferably it is composed of a material having a low ability to transport holes while having a function to transport electrons, and it is possible to improve the recombination probability of electrons and holes by blocking holes while transporting electrons.

In addition, the configuration of the electron transporting layer described above can be used as the hole blocking layer if necessary.

The hole blocking layer is preferably provided to be adjacent to the cathode side of the light emitting layer.

The thickness of the hole blocking layer is preferably in a range of from 3 to 100 nm and still more preferably in a range of from 5 to 30 nm.

As the material to be used in the hole blocking layer, the material to be used in the electron transporting layer described above is preferably used and the material to be used as the host compound described above is also preferably used in the hole blocking layer.

<Electron Injecting Layer>

An electron injecting layer (also referred to as an cathode buffer layer) is a layer to be provided between the cathode and the light emitting layer in order to lower the driving voltage and to improve the intensity of light emission, and it is described in detail in Part 2, Chapter 2 “Electrode Materials” (pages 123 to 166) of “Organic EL Devices and Their Frontier of Industrialization (Nov. 30, 1998 issued by NTS Co., Ltd.)”.

In the present invention, the electron injecting layer may be provided if necessary and present between the cathode and the light emitting layer or between the cathode and the electron transporting layer as described above.

The electron injecting layer is preferably a significantly thin film, and the thickness thereof is preferably in a range of from 0.1 to 5 nm although it also depends on the material. In addition, the electron injecting layer may be a nonuniform film in which the constituent material is intermittently present.

The electron injecting layer is also described in JP 6-325871 A, JP 9-17574 A, JP 10-74586 A, and the like in detail, and specific examples of a material to be preferably used in the electron injecting layer may include a metal typified by strontium or aluminum, an alkali metal compound typified by lithium fluoride, sodium fluoride, potassium fluoride, or the like, an alkaline earth metal compound typified by magnesium fluoride, calcium fluoride, or the like, a metal oxide typified by aluminum oxide, and a metal complex typified by lithium 8-hydroxyquinolate (Liq). It is also possible to use the electron transporting material described above.

The material to be used in the electron injecting layer may be used singly or plural kinds thereof may be used concurrently.

<Additives>

The organic functional layer in the present invention described above may further contain other additives.

Examples of the additives may include a halogen element such as bromine, iodine, or chlorine, a halogenated compound, and compounds, complexes, salts, and the like of an alkali metal such as Pd, Ca, or Na, an alkaline earth metal, and a transition metal.

The amount of the additive added can be arbitrarily determined, but it is preferably 1000 ppm or less, more preferably 500 ppm or less, and still more preferably 50 ppm or less with respect to the total percentage by mass of the layer to which the additive is added.

However, it is not in this range depending on the purpose of improving the transportability of electrons and holes, the purpose of favoring energy transfer of excitons, and the like.

<<Method of Forming Organic Functional Layer>>

The method of forming the organic functional layer (a hole injecting layer, a hole transporting layer, an electron blocking layer, a light emitting layer, a hole blocking layer, an electron transporting layer, an electron injecting layer, and the like) according to the present invention will be described.

The method of forming the organic functional layer is not particularly limited, and a conventionally known forming method such as a vacuum deposition method or a wet method (also referred to as a wet process) can be used.

As the wet method, there are a spin coating method, a casting method, an inkjet method, a printing method, a die coating method, a blade coating method, a roll coating method, a spray coating method, a curtain coating method, an LB method (Langmuir-Blodgett method), and the like, but a method, such as a die coating method, a roll coating method, an inkjet method, or a spray coating method, which exhibits high suitability for a roll-to-roll method is preferable from the viewpoint of easily obtaining a homogeneous thin film and of high productivity.

As the liquid medium in which the material of organic functional layer is dissolved or dispersed, it is possible to use an organic solvent such as a ketone such as methyl ethyl ketone or cyclohexanone, a fatty acid ester such as ethyl acetate, a halogenated hydrocarbon such as dichlorobenzene, an aromatic hydrocarbon such as toluene, xylene, mesitylene, or cyclohexylbenzene, an aliphatic hydrocarbon such as cyclohexane, decalin, or dodecane, DMF, or DMSO.

In addition, as a dispersing method, it is possible to disperse the material by a dispersing method such as ultrasonic wave and high shearing force dispersion or media dispersion.

In the case of employing the vapor deposition method for film formation, the vapor deposition conditions differ depending on the kind of compound to be used and the like, but in general, it is desirable to select the boat heating temperature in a range of from 50° C. to 450° C., the degree of vacuum in a range of from 1×10⁻⁶ to 1×10⁻² Pa, the vapor deposition rate in a range of from 0.01 to 50 nm/sec, the substrate temperature in a range of from −50° C. to 300° C., and the thickness in a range of from 0.1 nm to 5 μm and preferably in a range of from 5 to 200 nm.

For the formation of the organic functional layer, it is preferable to consistently fabricate from the hole injecting layer to the cathode by one time of vacuum evacuation, but the supporting substrate may be taken out in the middle and subjected to film formation by different methods. At this time, it is preferable to conduct the operation in a dry inert gas atmosphere.

<First Optical Adjustment Layer (10) and Second Optical Adjustment Layer (12)>

In the organic EL device of the present invention, the refractive index of the first optical adjustment layer is greater than the refractive index of the second optical adjustment layer from the viewpoint of increasing the light transmittance.

The effect of the present invention can be obtained when the refractive index of the first optical adjustment layer is greater than the refractive index of the second optical adjustment layer, but the difference in refractive index is preferably 0.3 or more, more preferably 0.6 or more, and most preferably 0.9 or more.

Incidentally, in the present invention, the refractive index is the value of refractive index at a wavelength of 550 nm measured in an environment of 23° C. and 55% RH. The refractive index can be measured and determined by using a commercially available ellipsometer.

It is more preferable as the first optical adjustment layer has a higher refractive index from the viewpoint of increasing the light transmittance.

The refractive index of the first optical adjustment layer is preferably 1.6 or more, more preferably 2.0 or more, and most preferably 2.3 or more.

It is more preferable as the second optical adjustment layer has a lower refractive index from the viewpoint of increasing the light transmittance.

The refractive index of the second optical adjustment layer is preferably 1.7 or less, more preferably 1.6 or less, and most preferably 1.4 or less.

The materials of the first optical adjustment layer and the second optical adjustment layer are not particularly limited as long as appropriate refractive indexes which satisfy the relation of refractive index described above can be obtained, and existing compounds can be utilized.

A compound capable of being subjected to vacuum film formation is preferable from the viewpoint that the film can be formed on the upper transparent electrode of the organic EL device without being damaged. In particular, compounds capable of being subjected to thermal vapor deposition and EB (electron gun) evaporation are preferable.

In addition, the material to be used in an organic EL device can also be used.

From the viewpoint of storage property of the organic EL device, it is preferable that the film formation ranges of the first optical adjustment layer and the second optical adjustment layer are set to narrower ranges than those of the sealing substrate and sealing film to be described later.

As the materials of the first optical adjustment layer and the second optical adjustment layer, it is possible to use, for example, Al₂O₃ (refractive index: 1.6), CeO₃ (refractive index: 2.2), Ga₂O₃ (refractive index: 1.5), HfO₂ (refractive index: 2.0), ITO (indium-tin oxide, refractive index 2.1), indium zinc oxide (refractive index: 2.1), MgO (refractive index: 1.7), Nb₂O₅ (refractive index 2.3), SiO₂ (refractive index: 1.5), Ta₂O₅ (refractive index: 2.2), TiO₂ (refractive index: 2.3 to 2.5), Y₂O₃ (refractive index: 1.9), ZnO (refractive index: 2.1), ZrO₂ (refractive index: 2.1), AlF₃ (refractive index: 1.4), CaF₂ (refractive index: 1.2 to 1.4), CeF₃ (refractive index: 1.6), GdF₃ (refractive index: 1.6), LaF₃ (refractive index: 1.59), LiF (refractive index: 1.3), MgF₂ (refractive index: 1.4), and NaF (refractive index: 1.3).

The second optical adjustment layer is preferably a metal fluoride from the viewpoint that the light transmittance after storage hardly changes.

Meanwhile, the first optical adjustment layer is preferably a sulfur-containing compound or a nitrogen-containing compound from the viewpoint that the light transmittance after storage hardly changes.

(Nitrogen-Containing Compound)

Examples of the nitrogen-containing compound may include hexane diamine, isocyanate, polyamide, polyurethane, an aromatic heterocyclic compound containing a nitrogen atom having an unshared electron pair which is not involved in aromaticity, and a low molecular weight organic compound containing a nitrogen atom. Among these, an aromatic heterocyclic compound containing a nitrogen atom having an unshared electron pair which is not involved in aromaticity is preferable.

[Low Molecular Weight Organic Compound Containing Nitrogen Atom]

As a low molecular weight organic compound containing a nitrogen atom, a compound having a melting point of 80° C. or higher and a molecular weight M in a range of from 150 to 1,200 is preferable. In addition, it is preferable that the low molecular weight organic compound containing a nitrogen atom exhibits great interaction with silver and the like, and examples thereof may include a nitrogen-containing heterocyclic compound and a phenyl group-substituted amine compound.

When the number n of [effective unshared electron pairs] with respect to the molecular weight M of the organic compound containing a nitrogen atom is defined as the effective unshared electron pair content rate [n/M], the low molecular weight organic compound containing a nitrogen atom is a compound selected so that this [n/M] is 2.0×10⁻³≤[n/M], and [n/M] is still more preferably 3.9×10⁻³≤[n/M].

As used herein, the term “effective unshared electron pair” refers to an unshared electron pair which is not involved in aromaticity and not coordinated to a metal among the unshared electron pairs of the nitrogen atoms contained in the compound.

Here, the aromaticity refers to an unsaturated cyclic structure in which atoms having π electrons are arranged in a ring shape, it is aromaticity according to the so-called “Hückel rule”, and it is conditioned on the fact that the number of electrons contained in the π electron system on the ring is “4n+2” (n=0 or a natural number).

The [effective unshared electron pair] as described above is selected depending on whether the unshared electron pair of the nitrogen atom is involved in the aromaticity or not regardless of whether the nitrogen atom itself having the unshared electron pair is a heteroatom constituting the aromatic ring or not.

For example, an unshared electron pair of a certain nitrogen atom is counted as one of [effective unshared electron pair] when the unshared electron pair of the nitrogen atom is not involved in aromaticity even if the nitrogen atom is a heteroatom constituting an aromatic ring.

On the contrary, an unshared electron pair of a certain nitrogen atom is not counted as an [effective unshared electron pair] when all the unshared electron pairs of the nitrogen atom are involved in the aromaticity even in a case in which the nitrogen atom is not a heteroatom constituting an aromatic ring.

Incidentally, in each compound, the number n of the [effective unshared electron pairs] described above is the same as the number of nitrogen atoms having the [effective unshared electron pair].

In a case in which the organic compound having a nitrogen atom is constituted by a plurality of compounds, it is preferable that the molecular weight M of the mixed compound obtained by mixing these compounds is determined based on the mixing ratio of the compounds, the number n of the sum of the [effective unshared electron pairs] with respect to the molecular weight M is determined as the average value of the effective unshared electron pair content rate [n/M], and this value is in the predetermined range described above, for example.

Hereinafter, as a low molecular weight organic compound containing a nitrogen atom, the following exemplary compounds No. 1 to No. 43 are presented as a compound in which the effective unshared electron pair content rate [n/M] satisfies 2.0×10⁻³≤[n/M].

Incidentally, in copper phthalocyanine of the exemplary compound No. 31, an unshared electron pair which is not coordinated to copper is counted as the [effective unshared electron pair] among the unshared electron pairs of the nitrogen atom.

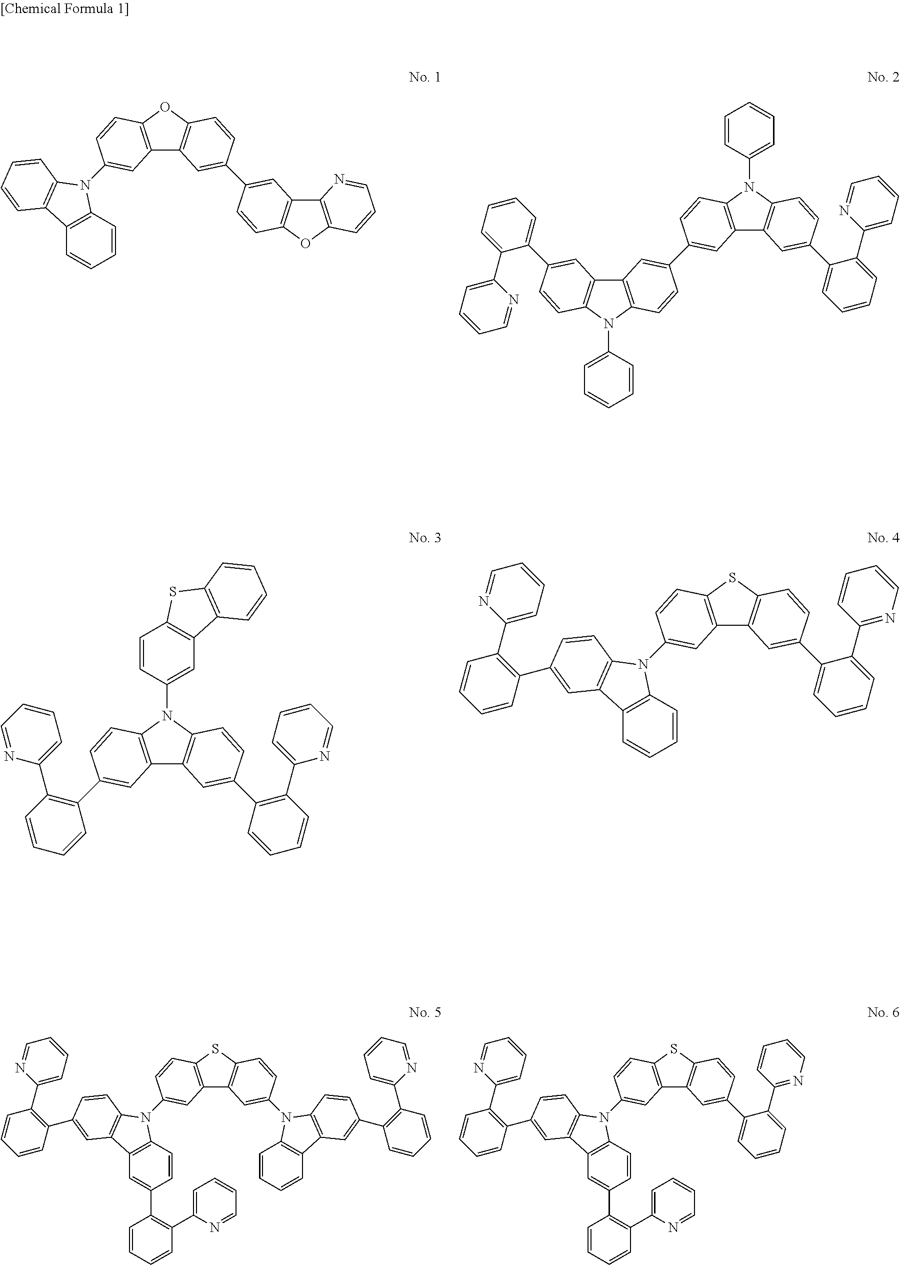

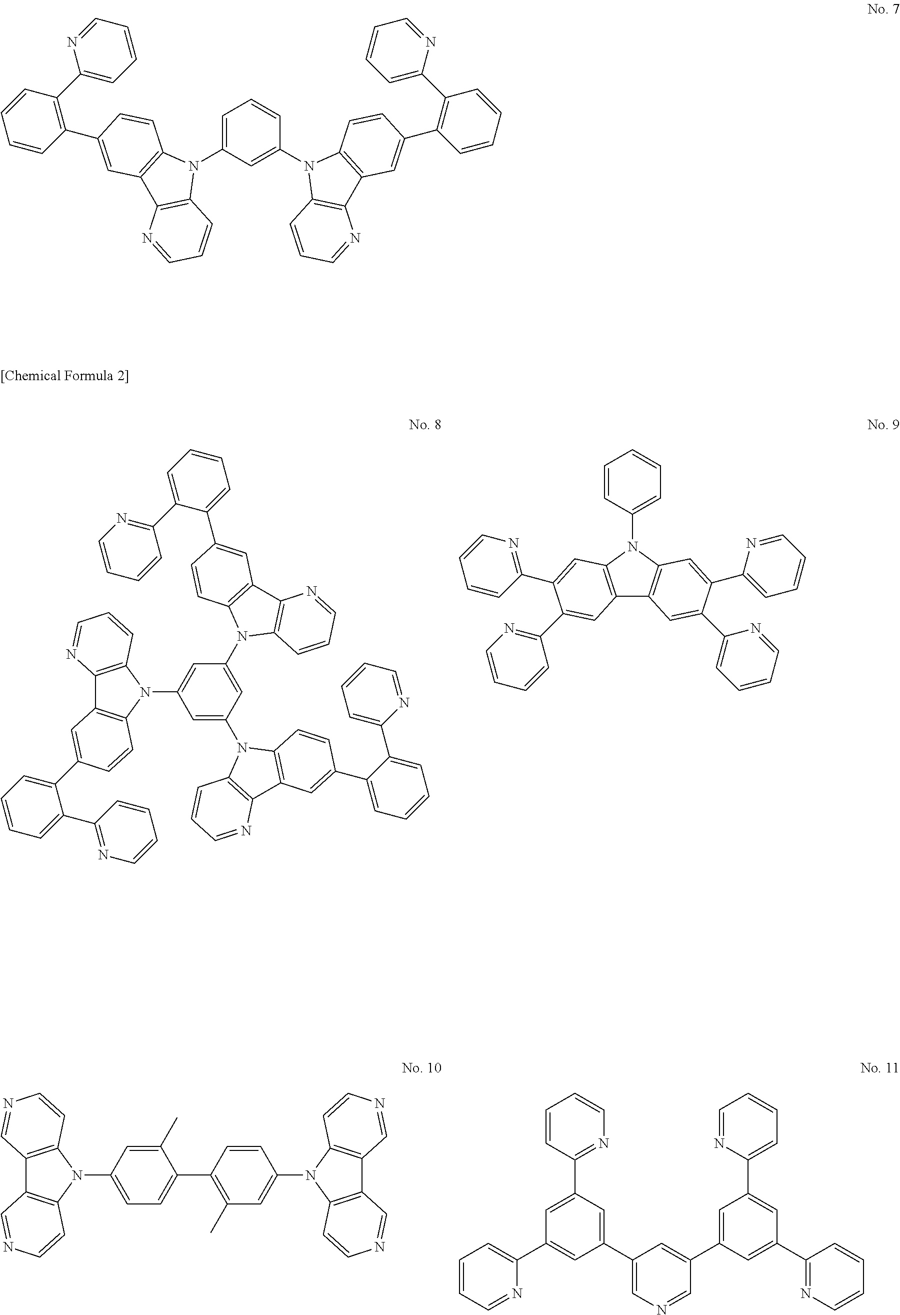 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1 ; c1ccc(-c2ccccc2-c2ccc3c(c2)c2ncccc2n3-c2cc(-n3c4ccc(-c5ccccc5-c5ccccn5)cc4c4ncccc43)cc(-n3c4ccc(-c5ccccc5-c5ccccn5)cc4c4ncccc43)c2)nc1 ; c1ccc(-n2c3cc(-c4ccccn4)c(-c4ccccn4)cc3c3cc(-c4ccccn4)c(-c4ccccn4)cc32)cc1 ; Cc1cc(-n2c3ccncc3c3cnccc32)ccc1-c1ccc(-n2c3ccncc3c3cnccc32)cc1C ; c1ccc(-c2cc(-c3cncc(-c4cc(-c5ccccn5)cc(-c5ccccn5)c4)c3)cc(-c3ccccn3)c2)nc1]

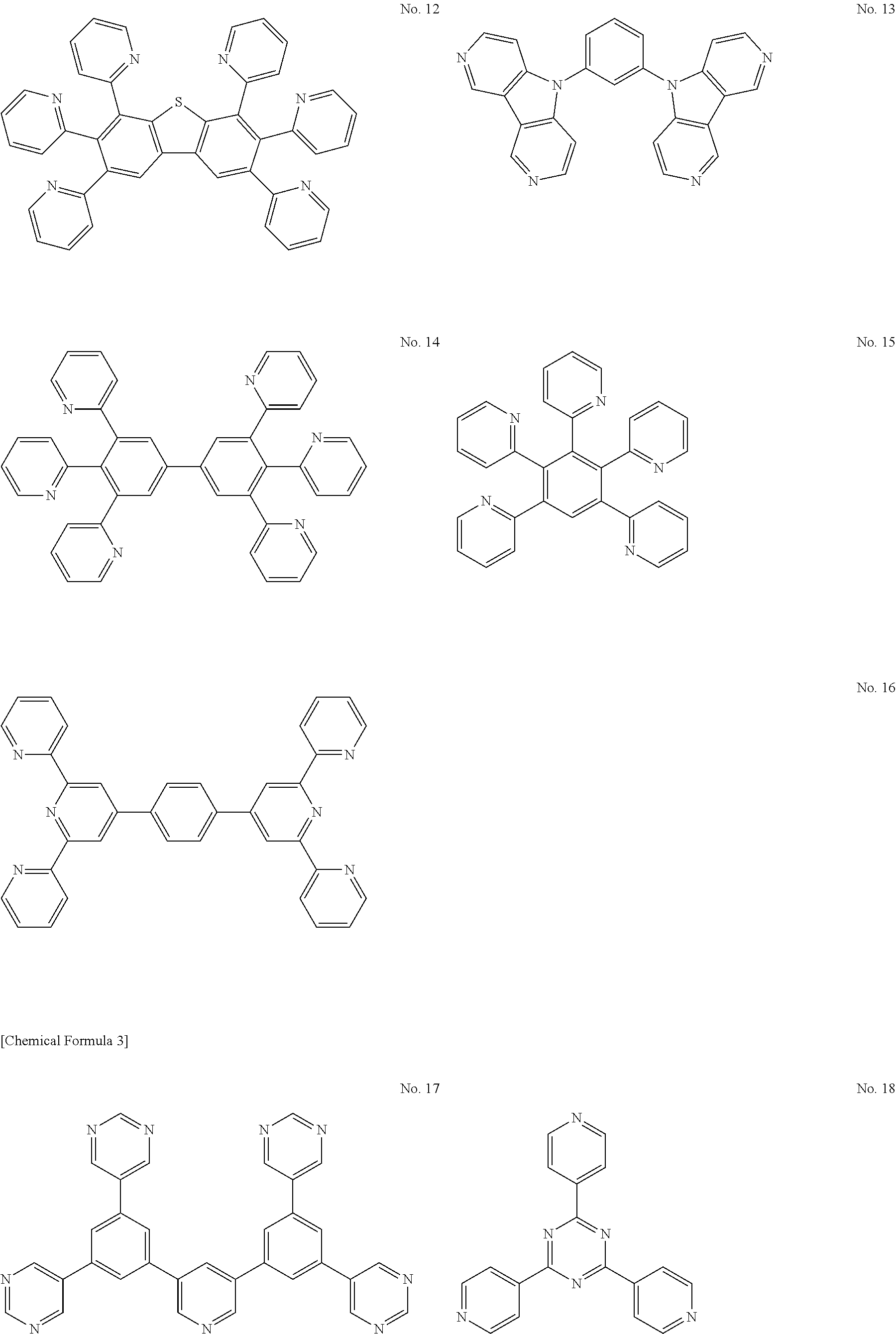

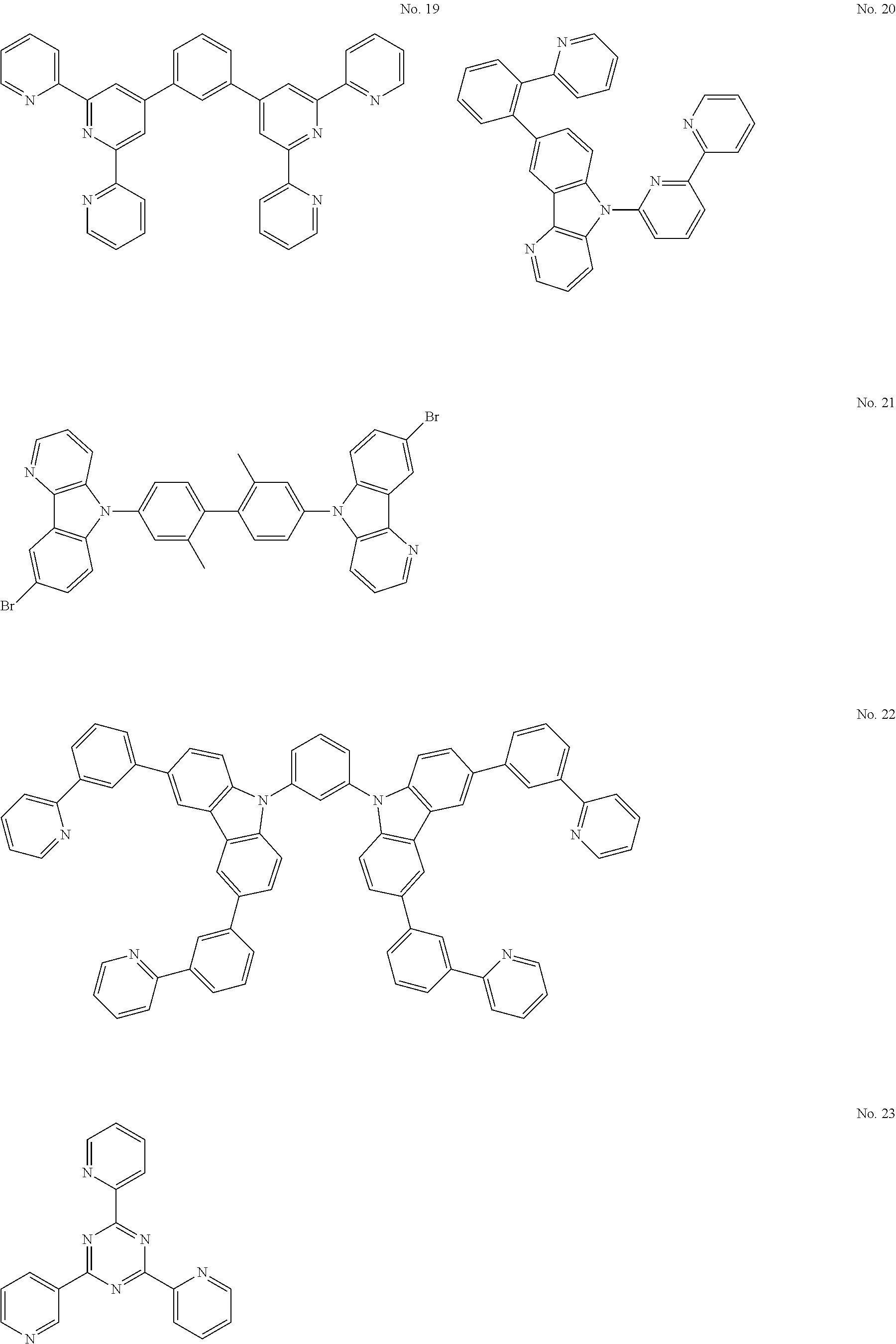 [SMILES: c1ccc(-c2cc(-c3cccc(-c4cc(-c5ccccn5)nc(-c5ccccn5)c4)c3)cc(-c3ccccn3)n2)nc1 ; c1ccc(-c2cccc(-n3c4ccc(-c5ccccc5-c5ccccn5)cc4c4ncccc43)n2)nc1 ; Cc1cc(-n2c3ccc(Br)cc3c3ncccc32)ccc1-c1ccc(-n2c3ccc(Br)cc3c3ncccc32)cc1C ; c1ccc(-c2cccc(-c3ccc4c(c3)c3cc(-c5cccc(-c6ccccn6)c5)ccc3n4-c3cccc(-n4c5ccc(-c6cccc(-c7ccccn7)c6)cc5c5cc(-c6cccc(-c7ccccn7)c6)ccc54)c3)c2)nc1 ; c1ccc(-c2nc(-c3cccnc3)nc(-c3ccccn3)n2)nc1]

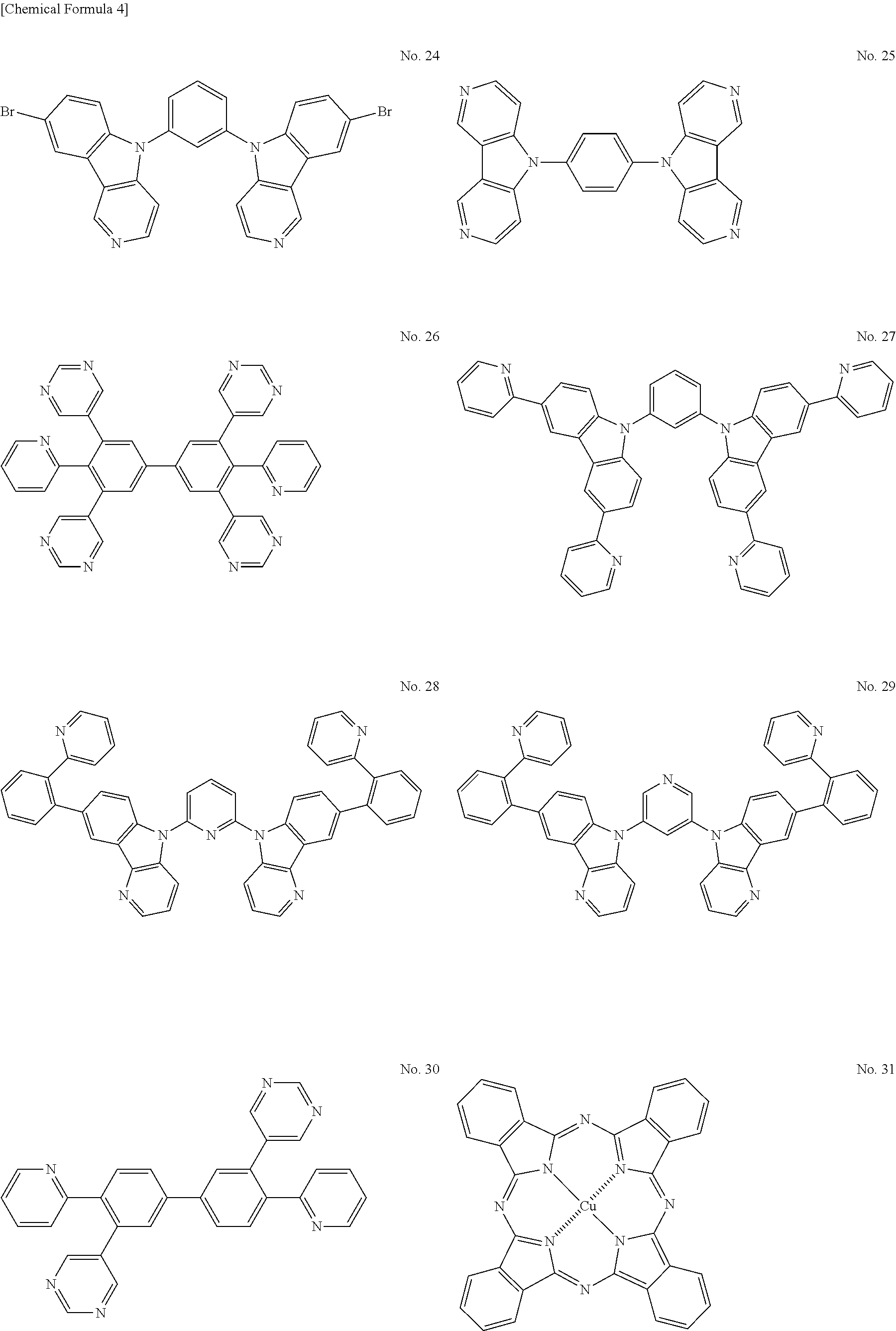

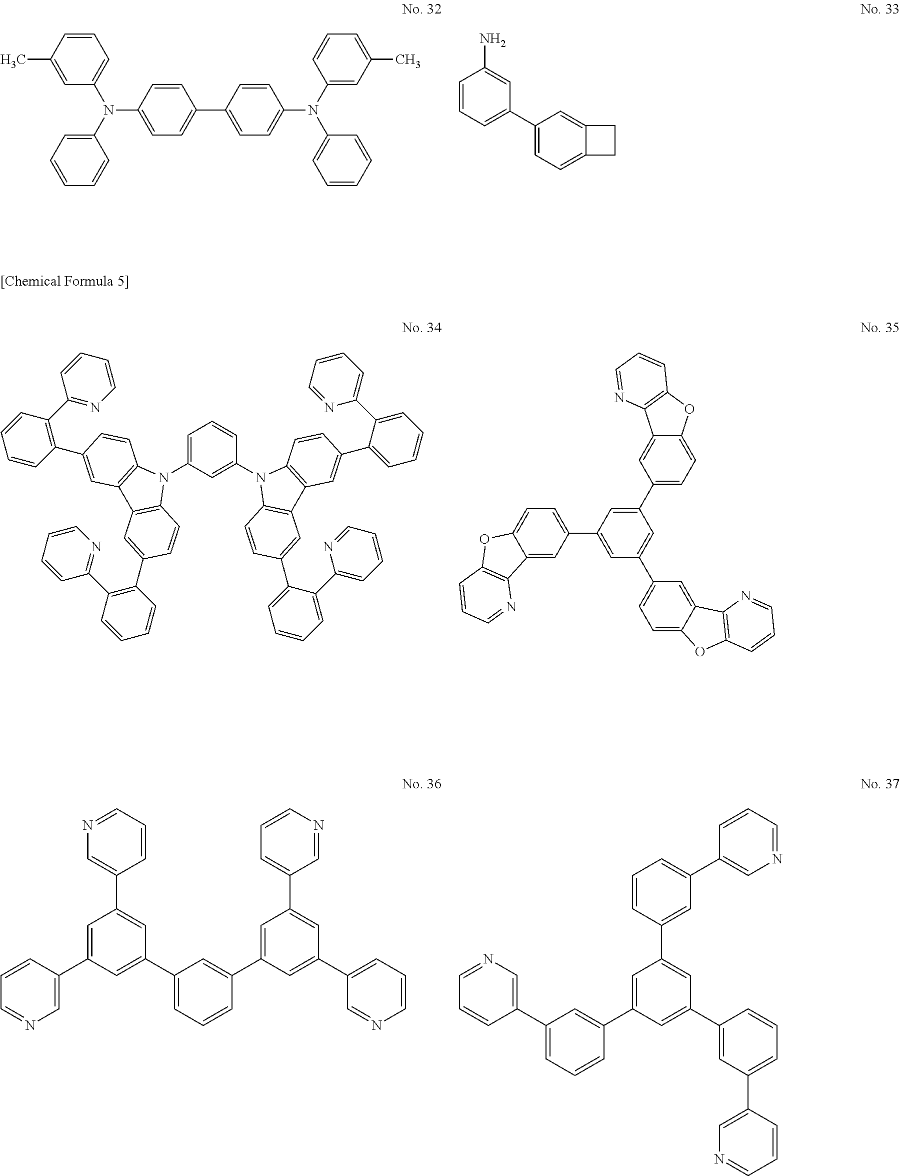

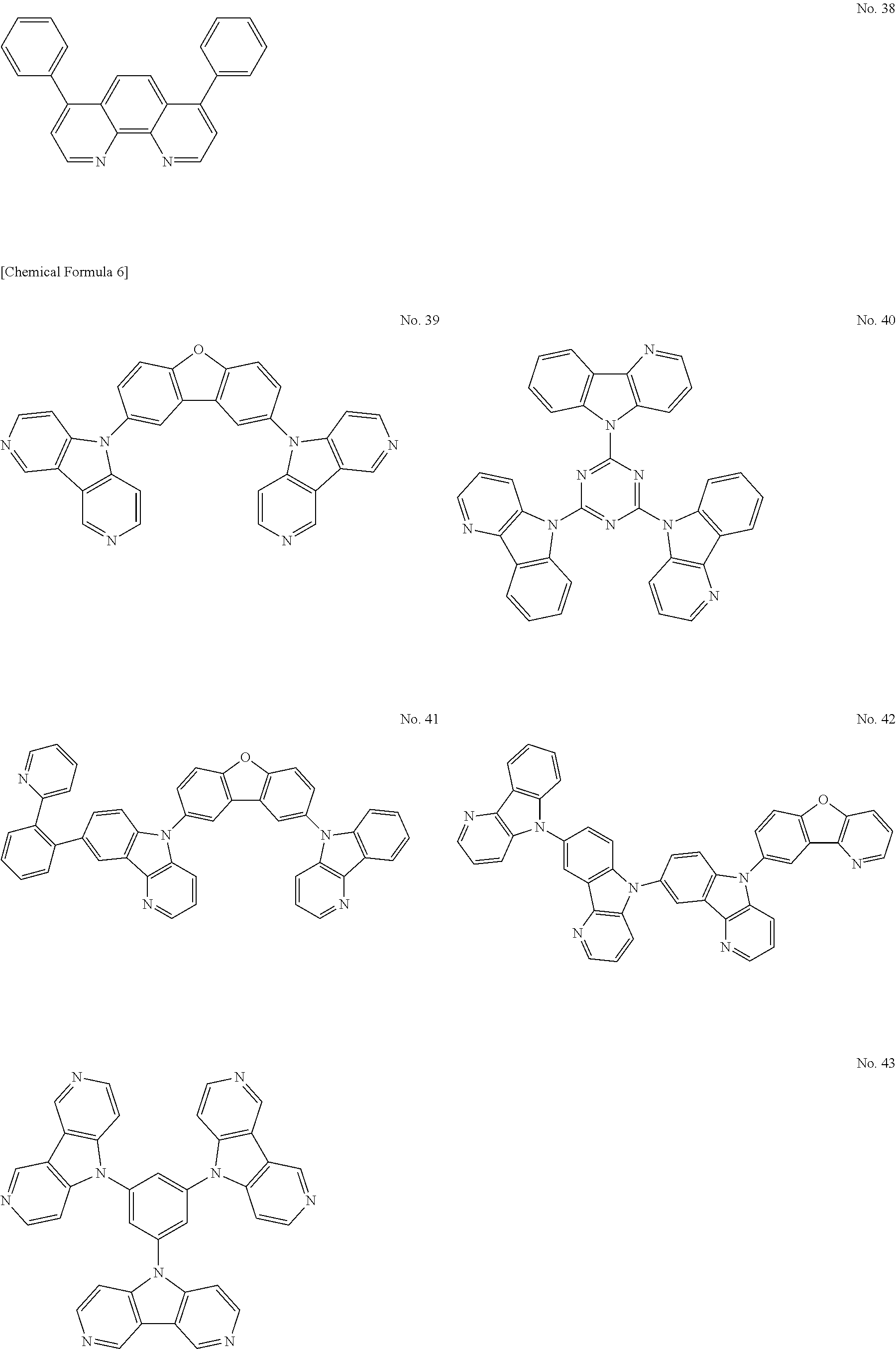 [SMILES: c1ccc(-c2ccnc3c2ccc2c(-c4ccccc4)ccnc23)cc1 ; c1cc2c(cn1)c1cnccc1n2-c1ccc2oc3ccc(-n4c5ccncc5c5cnccc54)cc3c2c1 ; c1ccc2c(c1)c1ncccc1n2-c1nc(-n2c3ccccc3c3ncccc32)nc(-n2c3ccccc3c3ncccc32)n1 ; c1ccc(-c2ccccc2-c2ccc3c(c2)c2ncccc2n3-c2ccc3oc4ccc(-n5c6ccccc6c6ncccc65)cc4c3c2)nc1 ; c1cnc2c(c1)oc1ccc(-n3c4ccc(-n5c6ccc(-n7c8ccccc8c8ncccc87)cc6c6ncccc65)cc4c4ncccc43)cc12 ; c1cc2c(cn1)c1cnccc1n2-c1cc(-n2c3ccncc3c3cnccc32)cc(-n2c3ccncc3c3cnccc32)c1]

The number (n) of [effective unshared electron pairs], the molecular weight (M), and the effective unshared electron pair content rate (n/M) of the compounds No. 1 to No. 43 are presented in Table 1.

TABLE 1

| Exemplary | Number of effective | Molecular | Effective unshared |
|---|---|---|---|
| compound | unshared electron pairs | weight | electron pair content rate |
| number | (n) | (M) | (n/M) |
| No. 1 | 1 | 500.55 | 0.0020 |
| No. 2 | 2 | 790.95 | 0.0025 |
| No. 3 | 2 | 655.81 | 0.0030 |
| No. 4 | 2 | 655.81 | 0.0030 |
| No. 5 | 3 | 974.18 | 0.0031 |
| No. 6 | 3 | 808.99 | 0.0037 |
| No. 7 | 4 | 716.83 | 0.0056 |
| No. 8 | 6 | 1036.19 | 0.0058 |
| No. 9 | 4 | 551.64 | 0.0073 |
| No. 10 | 4 | 516.60 | 0.0077 |
| No. 11 | 5 | 539.63 | 0.0093 |
| No. 12 | 6 | 646.76 | 0.0093 |
| No. 13 | 4 | 412.45 | 0.0097 |
| No. 14 | 6 | 616.71 | 0.0097 |
| No. 15 | 5 | 463.53 | 0.0108 |
| No. 16 | 6 | 540.62 | 0.0111 |
| No. 17 | 9 | 543.58 | 0.0166 |
| No. 18 | 6 | 312.33 | 0.0192 |
| No. 19 | 6 | 540.62 | 0.0111 |
| No. 20 | 4 | 475.54 | 0.0084 |
| No. 21 | 2 | 672.41 | 0.0030 |
| No. 22 | 4 | 1021.21 | 0.0039 |
| No. 23 | 6 | 312.33 | 0.0192 |
| No. 24 | 2 | 568.26 | 0.0035 |
| No. 25 | 4 | 412.45 | 0.0097 |
| No. 26 | 10 | 620.66 | 0.0161 |
| No. 27 | 4 | 716.63 | 0.0056 |
| No. 28 | 5 | 717.82 | 0.0070 |
| No. 29 | 5 | 717.82 | 0.0070 |
| No. 30 | 6 | 464.52 | 0.0129 |
| No. 31 | 4 | 576.10 | 0.0069 |
| No. 32 | 2 | 516.67 | 0.0039 |
| No. 33 | 1 | 195.26 | 0.0051 |
| No. 34 | 4 | 1021.21 | 0.0039 |
| No. 35 | 3 | 579.60 | 0.0052 |
| No. 36 | 4 | 538.64 | 0.0074 |
| No. 37 | 3 | 537.65 | 0.0056 |
| No. 38 | 2 | 332.40 | 0.0060 |
| No. 39 | 4 | 502.15 | 0.0080 |
| No. 40 | 6 | 579.19 | 0.0104 |
| No. 41 | 3 | 653.22 | 0.0046 |
| No. 42 | 4 | 667.21 | 0.0060 |
| No. 43 | 6 | 579.19 | 0.0104 |

Examples of the low molecular weight organic compound containing a nitrogen atom may include the following compounds No. 44 and No. 45 in addition to the compounds No. 1 to No. 43.

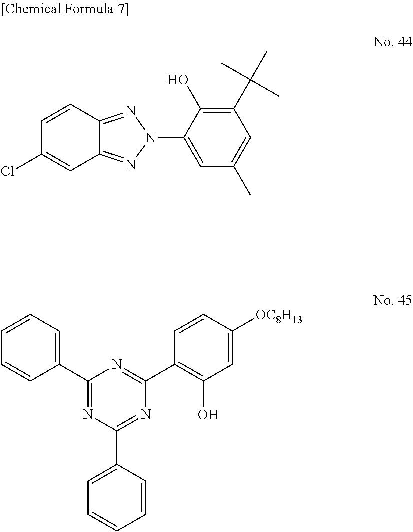

(Sulfur-Containing Compound)

The first optical adjustment layer according to the present invention preferably contains a compound containing a sulfur atom (sulfur-containing compound).

[Organic Compound Containing Sulfur Atom]

The organic compound containing a sulfur atom may have a sulfide bond (also referred to as a thioether bond), a disulfide bond, a mercapto group, a sulfone group, a thiocarbonyl bond and the like in the molecule, and particularly a sulfide bond and a mercapto group are preferable.

Specific examples thereof may include a sulfur-containing compound represented by the following general formulas (1) to (4).

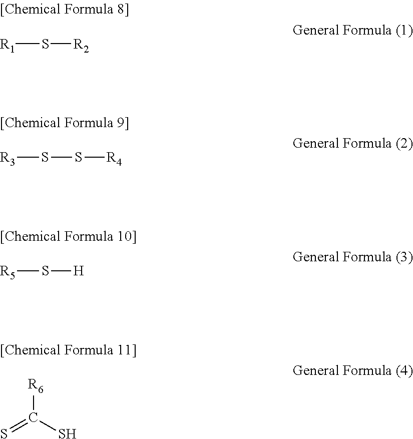

In the general formula (1), R₁ and R₂ each independently represent a substituent.

Examples of the substituent represented by R₁ and R₂ may include an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, and a pentadecyl group), a cycloalkyl group (for example, a cyclopentyl group and a cyclohexyl group), an alkenyl group (for example, a vinyl group and an allyl group), an alkynyl group (for example, an ethynyl group and a propargyl group), an aromatic hydrocarbon group (also referred to as an aromatic carbocyclic group, an aryl group, or the like, for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenylyl group), an aromatic heterocyclic group (for example, a furyl group, a thienyl group, a pyridyl group, a pyridazinyl group, a pyrimidinyl group, a pyrazinyl group, a triazinyl group, an imidazolyl group, a pyrazolyl group, a thiazolyl group, a quinazolinyl group, a carbazolyl group, a carbolinyl group, a diazacarbazolyl group (one obtained by substituting one of arbitrary carbon atoms constituting the carboline ring of a carbolinyl group with a nitrogen atom), and a phthalazinyl group), a heterocyclic group (for example, a pyrrolidyl group, an imidazolidyl group, a morpholyl group, and an oxazolidyl group), an alkoxy group (for example, a methoxy group, an ethoxy group, a propyloxy group, a pentyloxy group, a hexyloxy group, an octyloxy group, and a dodecyloxy group), a cycloalkoxy group (for example, a cyclopentyloxy group and a cyclohexyloxy group), an aryloxy group (for example, a phenoxy group and a naphthyloxy group), an alkylthio group (for example, a methylthio group, an ethylthio group, a propylthio group, a pentylthio group, a hexylthio group, an octylthio group, and a dodecylthio group), a cycloalkylthio group (for example, a cyclopentylthio group and a cyclohexylthio group), an arylthio group (for example, a phenylthio group and a naphthylthio group), an alkoxycarbonyl group (for example, a methyloxycarbonyl group, an ethyloxycarbonyl group, a butyloxycarbonyl group, an octyloxycarbonyl group, and a dodecyloxycarbonyl group), an aryloxycarbonyl group (for example, a phenyloxycarbonyl group and a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group), an acyloxy group (for example, an acetyloxy group, an ethylcarbonyloxy group, a butylcarbonyloxy group, an octylcarbonyloxy group, a dodecylcarbonyloxy group, and a phenylcarbonyloxy group), an amide group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, and a naphthylcarbonylamino group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, and a 2-pyridylaminocarbonyl group), a ureido group (for example, a methylureido group, an ethylureido group, a pentylureido group, a cyclohexylureido group, an octylureido group, a dodecylureido group, a phenylureido group, a naphthylureido group, and a 2-pyridylaminoureido group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, and a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, and a dodecylsulfonyl group), an arylsulfonyl group or a heteroarylsulfonyl group (for example, a phenylsulfonyl group, a naphthylsulfonyl group, and a 2-pyridylsulfonyl group), an amino group (for example, an amino group, an ethylamino group, a dimethylamino group, a butylamino group, a cyclopentylamino group, a 2-ethylhexylamino group, a dodecylamino group, an anilino group, a naphthylamino group, a 2-pyridylamino group, a piperidyl group (also referred to as a piperidinyl group), and a 2,2,6,6-tetramethylpiperidinyl group), a halogen atom (for example, a fluorine atom, a chlorine atom, and a bromine atom), a fluorohydrocarbon group (for example, a fluoromethyl group, a trifluoromethyl group, a pentafluoroethyl group, and a pentafluorophenyl group), a cyano group, a nitro group, a hydroxyl group, a mercapto group, a silyl group (for example, a trimethylsilyl group, a triisopropylsilyl group, a triphenylsilyl group, and a phenyldiethylsilyl group), a phosphoric acid ester group (for example, a dihexylphosphoryl group), a phosphorous acid ester group (for example, a diphenylphosphinyl group), and a phosphono group.

In the general formula (2), R₃ and R₄ each independently represent a substituent.

Examples of the substituent represented by R₃ and R₄ may include the same substituents as those for R₁ and R₂.

In the general formula (3), R₅ represents a substituent.

Examples of the substituent represented by R₅ may include the same substituents as those for R₁ and R₂.

In the general formula (4), R₆ represents a substituent.

Examples of the substituent represented by R₆ may include the same substituents as those for R₁ and R₂.

Specific examples of the organic compound which contains a sulfur atom is applicable to the first optical adjustment layer according to the present invention are described below.

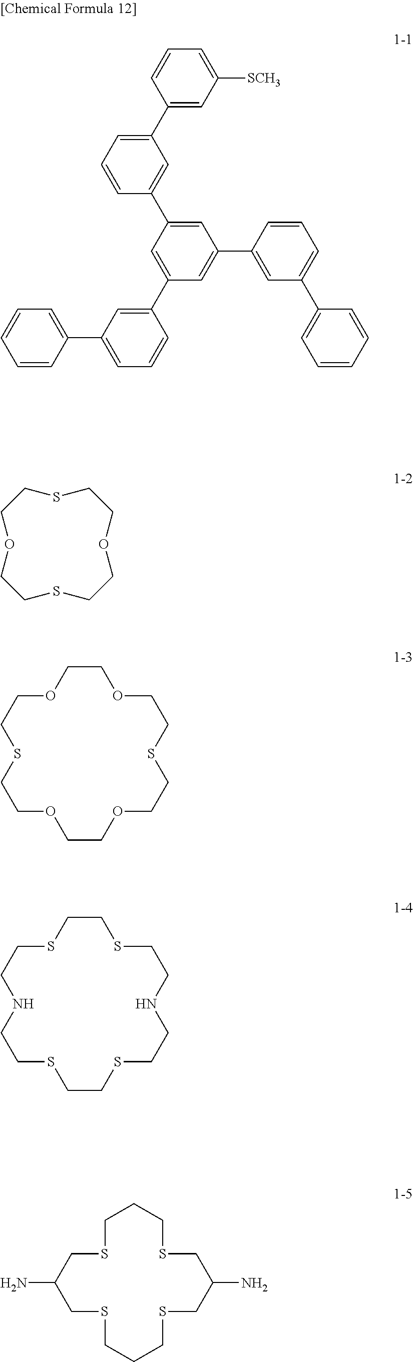 [SMILES: CSc1cccc(-c2cccc(-c3cc(-c4cccc(-c5ccccc5)c4)cc(-c4cccc(-c5ccccc5)c4)c3)c2)c1 ; C1CSCCOCCSCCO1 ; C1COCCSCCOCCOCCSCCO1 ; C1CSCCSCCNCCSCCSCCN1 ; NC1CSCCCSCC(N)CSCCCSC1]

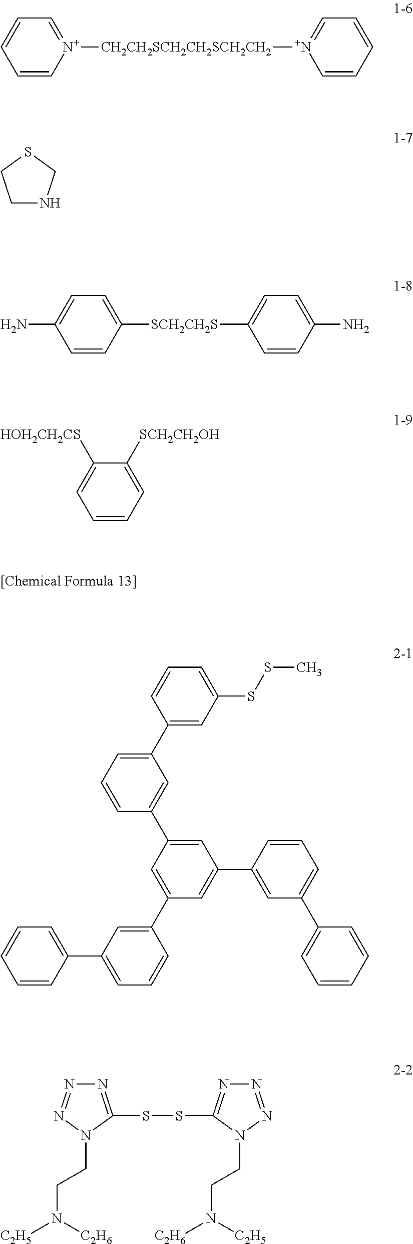

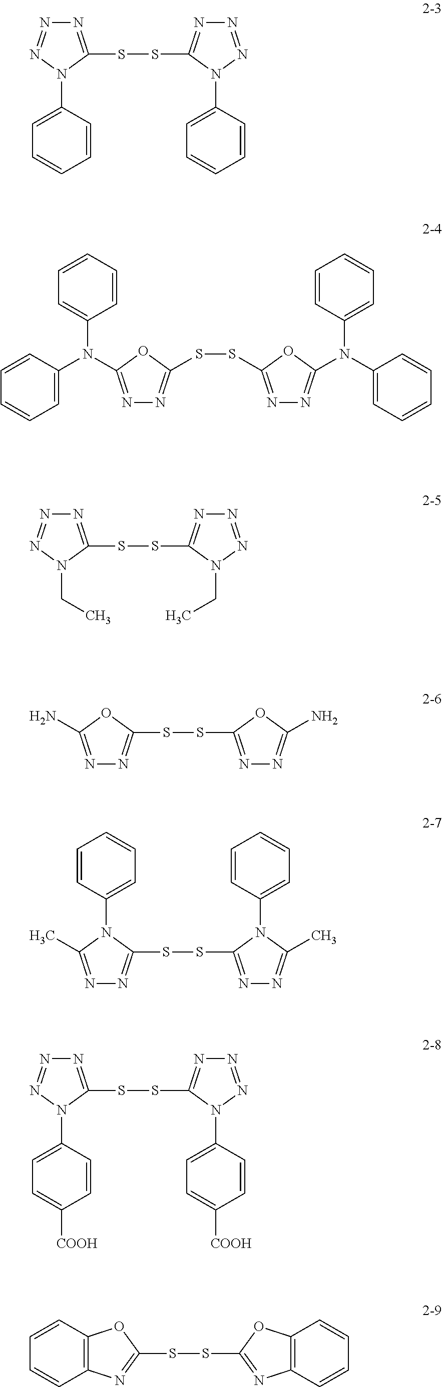

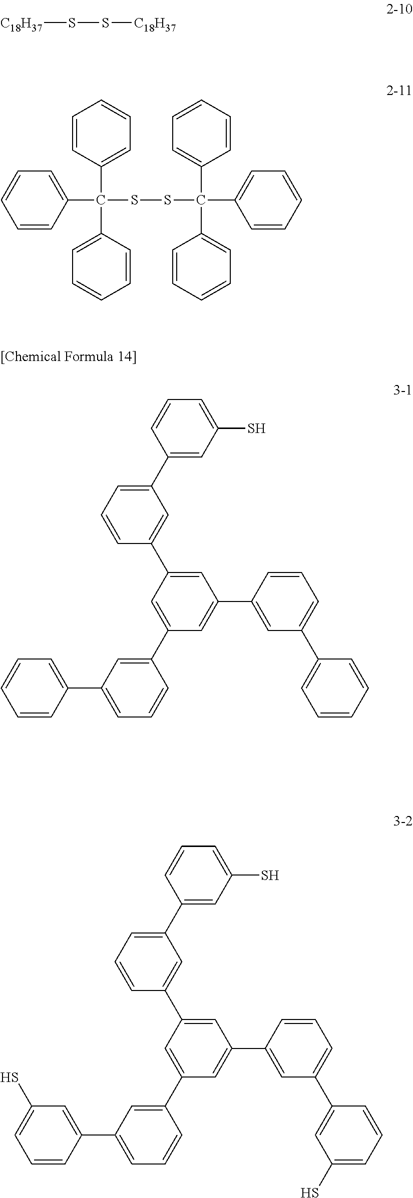

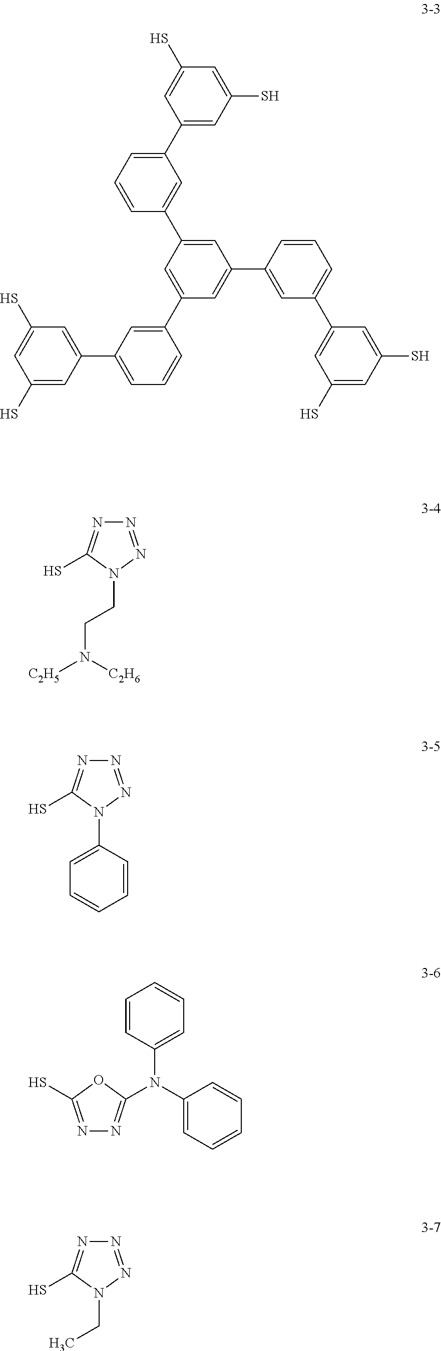

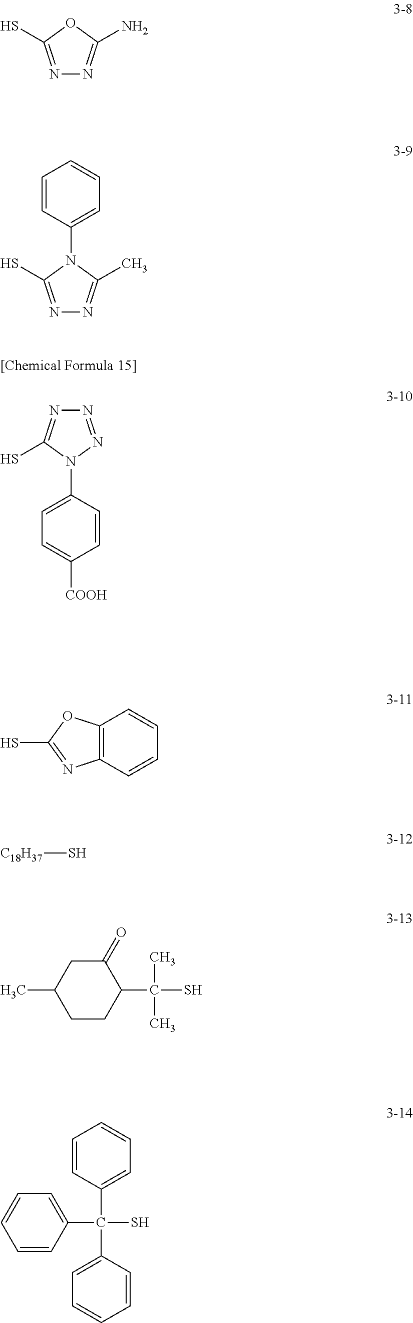

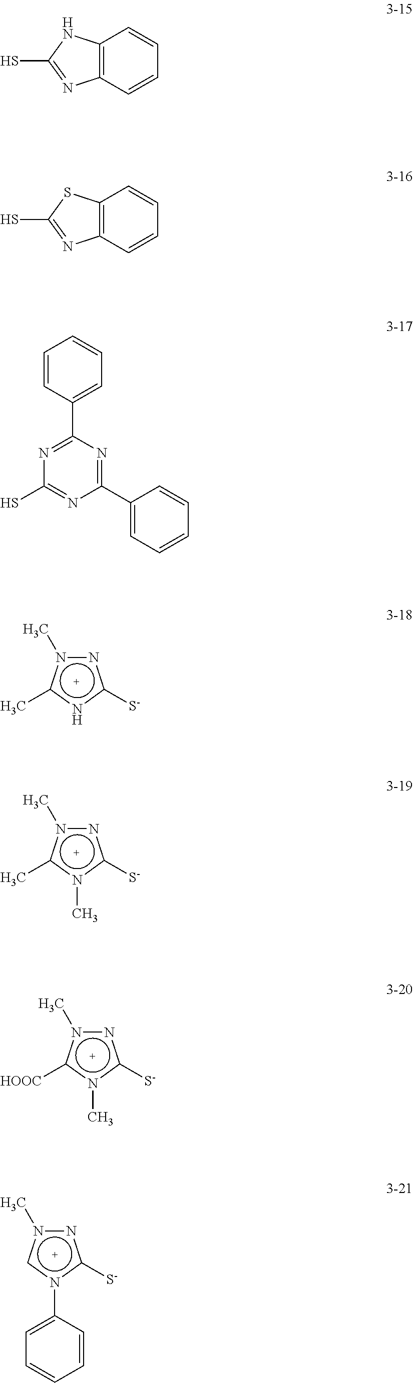

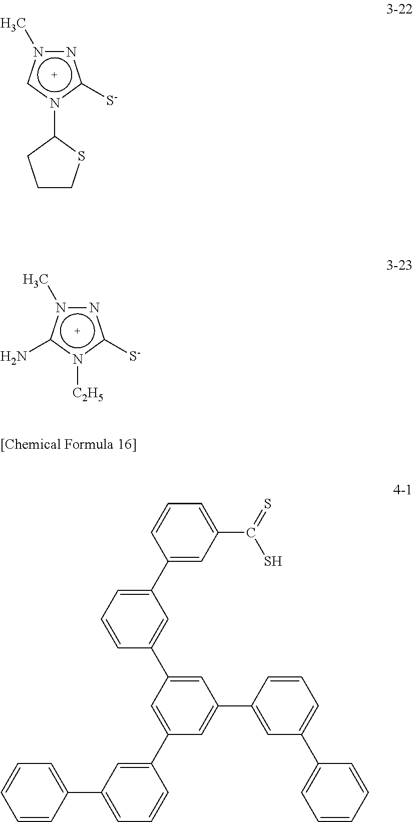

The thicknesses of the first optical adjustment layer and the second optical adjustment layer can be appropriately adjusted, but the thickness of the first optical adjustment layer is preferably in a range of from 10 to 500 nm, more preferably in a range of from 20 to 250 nm, and most preferably in a range of from 30 to 150 nm from the viewpoint of improving light transmittance. In the same manner, the thickness of the second optical adjustment layer is preferably in a range of from 10 to 500 nm, more preferably in a range of from 20 to 400 nm, and most preferably in a range of from 50 to 200 nm from the viewpoint of improving the light transmittance.

<<Sealing>>

Examples of the sealing means to be used for sealing the organic EL device of the present invention may include a method in which the electrode and the supporting substrate are pasted to the sealing substrate with an adhesive. The sealing substrate may be disposed so as to cover the display region of the organic EL device, and it may have a recessed plate shape or a flat plate shape. In addition, the electric insulating properties are not particularly limited.

As the sealing substrate, specifically the same material as that to be used in the supporting substrate described above can be used.

It is preferable to provide a gas barrier layer on the sealing substrate in the same manner as the supporting substrate. An antistatic layer may also be provided on the sealing substrate.

In the present invention, a polymer film can be preferably used since the organic EL device can be thinned. Furthermore, the polymer film is preferably one that has an oxygen transmission rate measured by a method conforming to JIS K 7126-1987 of 1×10⁻³ ml/(m²·24 h·atm) or less and a water vapor transmission rate (25±0.5° C. and a relative humidity of 90±2%) measured by a method conforming to JIS K 7129-1992 of 1×10⁻³ g/(m².24 h) or less.

Specific examples of the adhesive may include a photo curing and thermosetting type adhesive having a reactive vinyl group of an acrylic acid-based oligomer and a methacrylic acid-based oligomer and a moisture curing type adhesive such as 2-cyanoacrylic acid ester. Examples thereof may also include a heat and chemical curing type (two liquid mixing) such as an epoxy-based adhesive. Examples thereof may also include a hot melt type polyamide, polyester, and polyolefin. Examples thereof may also include an ultraviolet curing type epoxy resin adhesive of a cationically curing type.

Incidentally, the organic EL device is deteriorated by a heat treatment in some cases, and one that can be pasted and cured at from room temperature (25° C.) to 80° C. is thus preferable. In addition, a drying agent may be dispersed in the adhesive. For coating of the adhesive on the sealing substrate, a commercially available dispenser may be used or printing may be conducted as in screen printing.

In addition, it is also suitable to obtain a sealing film by coating the electrode and the organic functional layer on the outside of the electrode on the side facing the supporting substrate to sandwich the organic functional layer therebetween and forming layers of an inorganic substance and an organic substance in the form to be in contact with the supporting substrate. In this case, the material for forming the film may be a material which has a function to suppress penetration of substances, such as moisture and oxygen, which cause deterioration of the device, and for example, silicon oxide, silicon dioxide, silicon nitride, or the like can be used.

It is more preferable as the difference in refractive index between the sealing film and the adhesive is smaller from the viewpoint of increasing the transmittance.

Furthermore, it is preferable to provide a laminated structure of this inorganic layer and this layer composed of an organic material in order to improve brittleness of the film. The method of forming these films is not particularly limited, and for example, it is possible to use a vacuum deposition method, a sputtering method, a reactive sputtering method, a molecular beam epitaxy method, a cluster ion beam method, an ion plating method, a plasma polymerization method, an atmospheric pressure plasma polymerization method, a plasma CVD method, a laser CVD method, a thermal CVD method, a coating method, or the like.

<<Application>>

The organic EL device of the present invention can be used as a display device, a display, and various kinds of light emission sources.

Examples of the light emission sources may include lighting apparatuses (domestic use lighting and interior lighting), watches and liquid crystal backlights, signboard advertisements, traffic lights, light sources for optical storage media, light sources of electrophotographic copying machines, light sources of optical communication processors, and light sources of optical sensors, but the application is not limited thereto, and the organic EL device can be effectively used in applications particularly as backlight of a liquid crystal display device and an illumination light source.

### EXAMPLES

Hereinafter, the present invention will be specifically described with reference to Examples, but the present invention is not limited thereto.

### Example 1

<<Fabrication of Organic EL Device>>

<Fabrication of Organic EL Device 101>

(1) Preparation of Supporting Substrate

An antistatic layer containing an organic antistatic agent was formed on one surface of a 100 μm thick polyethylene terephthalate (PET) film (Lumirror (registered trademark) U48 manufactured by Toray Industries, Inc.) of which both surfaces were subjected to a surface activation treatment by the following method.

(1.1) Formation of Antistatic Layer (Organic Antistatic Agent 1)

A colloidal silica-containing monomer (A) was prepared according to the following method, and an antistatic hard coat agent (A) of an organic antistatic agent was prepared by using this colloidal silica-containing monomer (A). Thereafter, an antistatic layer was formed by using this organic antistatic agent.

(Preparation of Colloidal Silica-Containing Monomer (A))

To 130 parts by mass of colloidal silica (SiO₂ component: 30% by mass, average particle diameter: 20 nm, manufactured by NISSAN CHEMICAL INDUSTRIES, LTD.) dispersed by using ethyl acetate as a solvent, 30 parts by mass of 2-methacryloyloxyethyl isocyanate (MOI) (molecular weight: 155, manufactured by Showa Denko K.K.) and 0.1 part by mass of di-n-butyltin dilaurate (DBTDL) were added, and the mixture was stirred at room temperature (25° C.) for 24 hours. The reaction of the isocyanate group was confirmed by infrared spectroscopy, and ethyl acetate of the solvent was removed by using an evaporator, thereby obtaining a colloidal silica-containing monomer (A).

(Preparation of Antistatic Hard Coat Agent (A))

With 100 parts by mass of the colloidal silica-containing monomer (A) (nonvolatile component: 36% by mass) produced above, 5 parts by mass of a methyl ethyl ketone solution of Li⁺/CF₃SO₃⁻ (nonvolatile component: 50% by mass, manufactured by Sanko Chemical Industry Co., Ltd.) was mixed and stirred. As an initiator, 1 part by mass of Irgacure 907 (manufactured by BASF Japan) was added to the mixture, thereby preparing the antistatic hard coat agent (A) of an organic antistatic agent.

(Formation of Antistatic Layer)

Next, the prepared antistatic hard coat agent (A) of an organic antistatic agent was coated and dried on the supporting substrate under the condition that the thickness after curing became 10 μm. Thereafter, an ultraviolet irradiation treatment was conducted under the condition of 300 mJ by using a mercury lamp of 80 W/cm, thereby forming an antistatic layer composed of an organic antistatic agent.

(1.2) Formation of Ground Layer

Next, a ground layer having a thickness of 2 μm was formed on the other surface of the PET film. Specifically, a UV curing type resin OPSTAR (registered trademark) Z7527 (manufactured by JSR Corporation) was coated on the other surface so as to have a thickness after drying of 2 μm. After the coating film was dried at 80° C., a curing treatment to irradiate the coating film with ultraviolet light in an irradiation energy quantity of 0.5 J/cm² was conducted in the air by using a high pressure mercury lamp.

(1.3) Formation of Gas Barrier Layer

The PET film on which the ground layer was formed was cut out in a size of 120 mm×100 mm, and a silicon-containing polymer modified layer was formed on the ground layer in the following manner.

A 20% by mass dibutyl ether solution of uncatalyzed perhydropolysilazane (AQUAMICA NN120-20, manufactured by Merck Performance Materials) and a 20% by mass dibutyl ether solution of perhydropolysilazane containing amine-catalyzed (N,N,N′,N′-tetramethyl-1,6-diaminohexane) at 5% by mass of the solid components (AQUAMICA NAX 120-20, manufactured by Merck Performance Materials) were mixed together at a proportion of 4:1, and the mixture was further diluted appropriately with dibutyl ether in order to adjust the thickness, thereby preparing a coating liquid.

The coating liquid thus prepared was coated on the ground layer by using a die coater so as to have a thickness after drying of 100 nm and dried at 80° C. for 2 minutes. A Xe excimer lamp having a wavelength of 172 nm was used in the vacuum ultraviolet irradiation apparatus illustrated in FIG. 5, and a modification treatment to irradiate the coating film after being dried with vacuum ultraviolet light of 2.5 mJ/cm² by using this vacuum ultraviolet irradiation apparatus was conducted, thereby forming a silicon-containing polymer modified layer. When irradiating the coating film with vacuum ultraviolet light, purge was conducted with nitrogen so that the atmosphere had an oxygen concentration of 0.1% by volume. In addition, the temperature of the stage on which the PET film was placed was set to 80° C., and the conveying speed of the stage was set to 0.5 m/min.

In a vacuum ultraviolet irradiation apparatus 100 illustrated in FIG. 5, a resin film (supporting substrate) 2 is placed on a stage 104 and conveyed in a chamber 102. The water vapor inside the chamber 102 is removed by exhaust ventilation, and the oxygen concentration is constantly adjusted by introduction of an inert gas. The stage 104 has a built-in heater and is thus capable of heating the resin film 2.

The interior of the chamber 102 is divided into three zones in the conveying direction V of the resin film 2 by a shielding plate 106, and a plurality of Xe excimer lamps 108 are installed in the central zone. The Xe excimer lamp 108 is supported by a holder 110 having a built-in power supply and is controlled to be turned on. The resin film 2 on which a coating film of a silicon-containing polymer is formed can be irradiated with vacuum ultraviolet light by passing through this zone in which the Xe excimer lamps 108 are installed.

Subsequently, a silicon compound layer having a thickness of 300 nm was respectively formed by a plasma CVD method, thereby obtaining a supporting substrate having a gas barrier layer.

The film forming conditions for the silicon compound layer are as follows.

Amount of raw material gas (hexamethyldisiloxane:HMDSO) supplied: 50 sccm (Standard Cubic Centimeter per Minute)

Amount of oxygen gas (O₂) supplied: 500 sccm

Degree of vacuum in vacuum chamber: 3 Pa

Electric power applied from power supply for plasma generation: 1.2 kW

Frequency of power supply for plasma generation: 80 kHz

Conveying speed of film: 0.5 m/min

Furthermore, the silicon-containing polymer modified layer was coated thereon to have a film thickness of 300 nm and cured by ultraviolet light in the same manner as above.

(2) Formation of Anode (Lower Transparent Electrode)

A target of In₂O₃:ZnO (90% by mass: 10% by mass) was attached to a commercially available sputtering apparatus, and an anode which was composed of IZO and had a thickness of 250 nm was formed under the following conditions.

Total pressure: 0.4 Mpa

Flow rate of argon: 99 sccm

Flow rate of oxygen: 1 sccm

Output: 5 W/cm²

(3) Formation of Organic Functional Layer

Various kinds of organic layers were formed on the anode thus fabricated in the following manner.

In each of the crucibles for vapor deposition in the vacuum deposition apparatus, the constituent material of each layer was filled in an optimum amount for device fabrication. As the crucible for vapor deposition, one fabricated from a material for resistance heating made of molybdenum or tungsten was used.

After the pressure was decreased to a degree of vacuum of 1×10⁻⁴ Pa, the crucible for vapor deposition containing the following compound M-2 was energized and heated to vapor deposit the compound M-2 on the anode at a deposition rate of 0.1 nm/sec, thereby forming a hole injecting and transporting layer having a thickness of 40 nm.

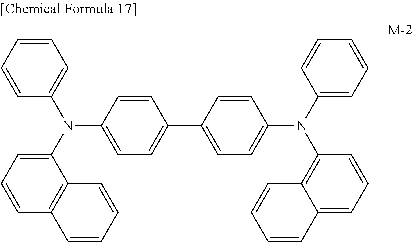 [SMILES: c1ccc(N(c2ccc(-c3ccc(N(c4ccccc4)c4cccc5ccccc45)cc3)cc2)c2cccc3ccccc23)cc1]

Subsequently, the following compound BD-1 and the following compound H-1 were subjected to codeposition at a deposition rate of 0.1 nm/sec so that the concentration of the compound BD-1 was 5% by mass, thereby forming a fluorescent light emitting layer which emitted blue light and had a thickness of 15 nm.

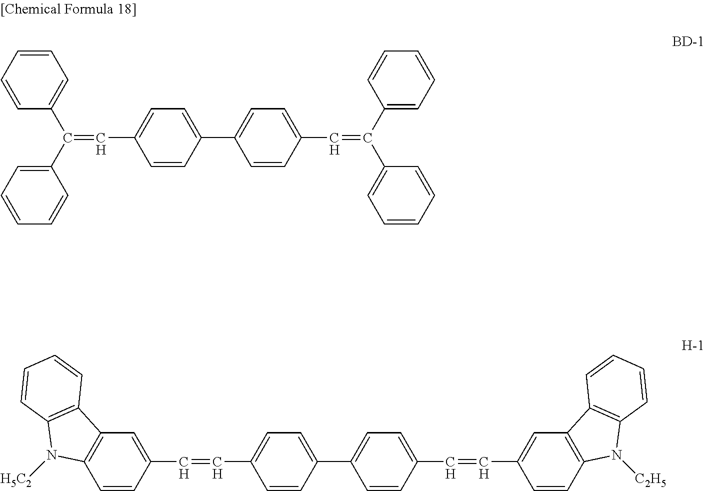

Subsequently, the following compound GD-1, the following compound RD-1, and the following compound H-2 were subjected to codeposition at a deposition rate of 0.1 nm/sec so that the concentration of the compound GD-1 was 17% by mass and the concentration of the compound RD-1 was 0.8%, thereby forming a phosphorescent light emitting layer which exhibited yellow color and had a thickness of 15 nm.

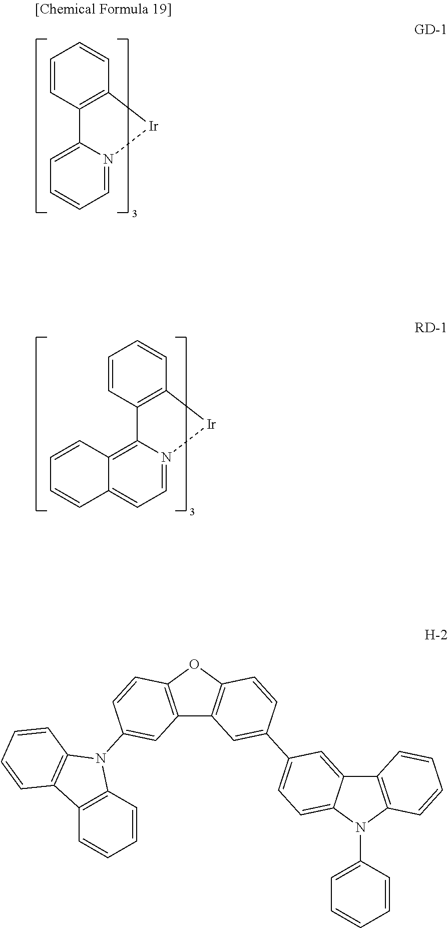

Thereafter, the following compound ET-1 was vapor deposited thereon at a deposition rate of 0.1 nm/sec, thereby forming an electron transporting layer having a thickness of 30 nm.

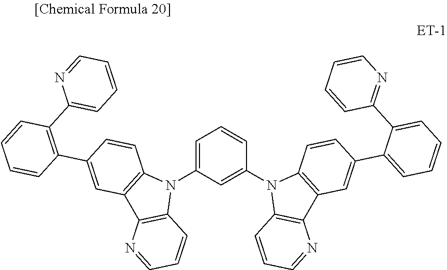 [SMILES: c1ccc(-c2ccccc2-c2ccc3c(c2)c2ncccc2n3-c2cccc(-n3c4ccc(-c5ccccc5-c5ccccn5)cc4c4ncccc43)c2)nc1]

Furthermore, an electron injecting layer of LiF was formed thereon to have a thickness of 1.5 nm, and aluminum was then vapor deposited thereon to have a thickness of 0.6 nm.

(4) Formation of Cathode (Upper Transparent Electrode)

Subsequently, silver was vapor deposited thereon at a deposition rate of 0.3 nm/sec to have a thickness of 8 nm, thereby obtaining a cathode.

(5) Formation of Optical Adjustment Layer

Subsequently, anthracene was vapor deposited thereon at 0.1 nm/sec, thereby forming an optical adjustment layer (to be a first optical adjustment layer) having a thickness of 45 nm.

(6) Sealing

(6.1) Preparation of Adhesive Composition

In toluene, 100 parts by mass of “Oppanol B50 (manufactured by BASF, Mw: 340,000)” as a polyisobutylene-based resin (A), 30 parts by mass of “Nisseki Polybutene Grade HV-1900 (manufactured by Nippon Oil Corporation, Mw: 1900)” as a polybutene resin (B), 0.5 part by mass of “TINUVIN 765 (manufactured by BASF Japan, having a tertiary hindered amine group)” as a hindered amine-based light stabilizer (C), 0.5 part by mass of “IRGANOX 1010 (manufactured by BASF Japan, having two tertiary butyl groups at the β position of the hindered phenol group”) as a hindered phenol-based antioxidant (D), and 50 parts by mass of “Eastotac H-100L Resin (manufactured by Eastman Chemical Company)” as a cyclic olefin-based polymer (E) were dissolved, thereby preparing an adhesive composition having a solid concentration of about 25%.

(6.2) Fabrication of Sealing Substrate

The supporting substrate with a gas barrier fabricated above was prepared and used as a sealing substrate as it was. Next, a solution of the adhesive composition thus prepared was coated on the surface to be the cathode side (gas barrier layer side) of the sealing substrate so that the thickness of the adhesive layer to be formed after drying was 20 μm and dried at 120° C. for 2 minutes, thereby forming an adhesive layer. Next, the release-treated surface of a polyethylene terephthalate film having a thickness of 38 μm as a release sheet was stuck to the surface of the adhesive layer thus formed, thereby fabricating a sealing substrate.

The sealing substrate fabricated by the method described above was left to stand for 24 hours or longer in a nitrogen atmosphere.

After being left to stand, the release sheet was removed from the sealing substrate and the sealing substrate was laminated in a form to cover the cathode of the organic light emitting device by using a vacuum laminator heated to 80° C. Furthermore, the resultant was heated at 120° C. for 30 minutes and sealed, thereby fabricating an organic EL device 101.

<Fabrication of Organic EL Device 102>

An organic EL device 102 was fabricated in the same manner as in the fabrication of the organic EL device 101 except that the (first) optical adjustment layer and the second optical adjustment layer were formed as follows.

(Formation of First Optical Adjustment Layer)

Magnesium fluoride (MgF₂) set in a crucible for electron-gun-vapor deposition was vapor deposited on the cathode by using an electron gun, thereby forming a first optical adjustment layer. The deposition rate was set to about 1 nm/sec.

(Formation of Second Optical Adjustment Layer)

Anthracene was vapor deposited on the first optical adjustment layer at 0.1 nm/sec, thereby forming a second optical adjustment layer having a thickness of 45 nm.

<Fabrication of Organic EL Devices 103 to 111>

Organic EL devices 103 to 111 were fabricated in the same manner as in the fabrication of the organic EL device 102 except that the materials and thicknesses of the first optical adjustment layer and the second optical adjustment layer were changed as described in Table 2.

The method of forming the optical adjustment layer using each of the materials described in Table 2 is as follows.

MoO₃: heated and vapor deposited at a deposition rate of about 0.2 nm/sec.

Nb₂O₅: vapor deposited at a deposition rate of about 1 nm/sec by using an electron gun.

TiO₂: vapor deposited at a deposition rate of about 1 nm/sec by using an electron gun.

CaF₂: vapor deposited at a deposition rate of about 1 nm/sec by using an electron gun.

MgF₂: vapor deposited at a deposition rate of about 1 nm/sec by using an electron gun.

NaF: heated and vapor deposited at a deposition rate of about 0.2 nm/sec.

Organic Compound A: heated and vapor deposited at a deposition rate of about 0.1 nm/sec.

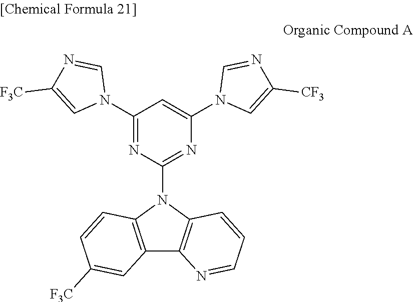 [SMILES: FC(F)(F)c1ccc2c(c1)c1ncccc1n2-c1nc(-n2cnc(C(F)(F)F)c2)cc(-n2cnc(C(F)(F)F)c2)n1]

<<Evaluation>>

<Measurement of Light Transmittance>

For each of the organic EL devices thus fabricated, the total light transmittance (%) of this sample was measured by using NDH 7000 manufactured by NIPPON DENSHOKU INDUSTRIES CO., LTD. in conformity to JIS K 7361.

In addition, the difference in visual aspect between the light emitting region and the non-light emitting region (the region in which only the cathode was not formed) was evaluated according to the following evaluation criteria by visual evaluation.

A: difference in light transmittance (difference in transparency) between light emitting region and non-light emitting region is hardly observed.

B: difference in light transmittance between light emitting region and non-light emitting region is slightly observed.

C: difference in light transmittance between light emitting region and non-light emitting region is observed but there is no problem for practical use.

D: difference in light transmittance between light emitting region and non-light emitting region is great and there is problem for practical use.

The evaluation results are presented in Table 2. Incidentally, the light transmittance of the organic EL devices 102 to 111 is presented as a relative value with respect to the light transmittance of the organic EL device 101 taken as 100.

TABLE 2

| Organic | | First optical adjustment layer | | | Second optical adjustment layer | | |
|---|---|---|---|---|---|---|---|
| EL device | Transparent | | Thickness | Refractive | | Thickness | Refractive |
| No. | electrode | Material | [nm] | index | Material | [nm] | index |
| 101 | Al (0.6 nm)/Ag | Anthracene | 45 | 1.7 | — | — | — |
| | (8 nm) | | | | | | |
| 102 | Al (0.6 nm)/Ag | MgF₂ | 120 | 1.3 | Anthracene | 45 | 1.7 |
| | (8 nm) | | | | | | |
| 103 | Al (0.6 nm)/Ag | Anthracene | 45 | 1.7 | MgF₂ | 120 | 1.3 |
| | (8 nm) | | | | | | |
| 104 | Al (0.6 nm)/Ag | MoO₃ | 40 | 2.0 | MgF₂ | 120 | 1.3 |
| | (8 nm) | | | | | | |
| 105 | Al (0.6 nm)/Ag | Nb₂O₅ | 30 | 2.3 | MgF₂ | 120 | 1.3 |
| | (8 nm) | | | | | | |
| 106 | Al (0.6 nm)/Ag | TiO₂ | 27 | 2.4 | MgF₂ | 120 | 1.3 |
| | (8 nm) | | | | | | |
| 107 | Al (0.6 nm)/Ag | Anthracene | 45 | 1.7 | CaF₂ | 120 | 1.3 |
| | (8 nm) | | | | | | |
| 108 | Al (0.6 nm)/Ag | Anthracene | 45 | 1.7 | CaF₃ | 110 | 1.6 |
| | (8 nm) | | | | | | |
| 109 | Al (0.6 nm)/Ag | Anthracene | 45 | 1.7 | NaF | 120 | 1.3 |
| | (8 nm) | | | | | | |
| 110 | Al (0.6 nm)/Ag | Anthracene | 45 | 1.7 | Organic | 110 | 1.6 |
| | (8 nm) | | | | Compound A | | |
| 111 | Al (0.6 nm)/Ag | TiO₂ | 30 | 2.4 | Anthracene | 115 | 1.7 |
| | (8 nm) | | | | | | |

| | | | | | Difference in | |
|---|---|---|---|---|---|---|
| | | | | Light | light | |
| Organic | Sealing film | | | transmittance | transmittance | |
| EL device | | Thickness | Refractive | (relative | (visual | |
| No. | Material | [nm] | index | value) | evaluation) | Remark |
| 101 | — | — | — | 100 | D | Comparative |
| | | | | | | Example |
| 102 | — | — | — | 90 | D | Comparative |
| | | | | | | Example |
| 103 | — | — | — | 110 | B | Present |
| | | | | | | invention |
| 104 | — | — | — | 112 | B | Present |
| | | | | | | invention |
| 105 | — | — | — | 115 | A | Present |
| | | | | | | invention |
| 106 | — | — | — | 116 | A | Present |
| | | | | | | invention |
| 107 | — | — | — | 110 | B | Present |
| | | | | | | invention |
| 108 | — | — | — | 108 | C | Present |
| | | | | | | invention |
| 109 | — | — | — | 110 | B | Present |
| | | | | | | invention |
| 110 | — | — | — | 108 | C | Present |
| | | | | | | invention |
| 111 | — | — | — | 113 | A | Present |
| | | | | | | invention |

As is apparent from Table 2, it has been demonstrated that the organic EL devices of the present invention have a higher light transmittance and a smaller visual difference between the light emitting region and the non-light emitting region as compared to the organic EL devices of Comparative Examples.

From the above, it is understood that the fact that the refractive index of the first optical adjustment layer is greater than the refractive index of the second optical adjustment layer and the upper transparent electrode and the first optical adjustment layer, and the first optical adjustment layer and the second optical adjustment layer are provided to be in direct contact with each other, respectively is useful to provide an organic EL device having a high light transmittance and a small visual difference between a light emitting region and a non-light emitting region (a difference in light transmittance between a light emitting region and a non-light emitting region is small).

### Example 2

<<Fabrication of Organic EL Device>>

<Fabrication of Organic EL Device 201>

An organic EL device 201 was fabricated in the same manner as in the fabrication of the organic EL device 103 of Example 1 except that a sealing film was formed between the second optical adjustment layer and the adhesive as follows.

(Formation of Sealing Film)

A silicon nitride film was formed by using a deposition-up type plasma CVD film forming apparatus under the following conditions, thereby forming a sealing film. The film thickness of the silicon nitride film was set to 300 nm.

The silicon nitride film was formed by using a plasma CVD film forming apparatus equipped with an electrode provided so as to face a base material, a high frequency power supply for supplying plasma excitation power to this electrode, a bias power supply for supplying a bias power to a holding member to hold the base material, and a gas supply means for supplying a carrier gas or a raw material gas toward the electrode.

Silane gas (SiH₄), ammonia gas (NH₃), nitrogen gas (N₂), and hydrogen gas (H₂) were used as the film forming gases. The amount of these gases supplied were 100 sccm for the silane gas, 200 sccm for the ammonia gas, 500 sccm for the nitrogen gas, and 500 sccm for the hydrogen gas.

In addition, the pressure for film formation was set to 50 Pa.

A plasma excitation power of 3000 W was supplied from a high frequency power supply to the electrode at a frequency of 13.5 MHz. Furthermore, a bias power of 500 W was supplied from the bias power supply to the holding member.

<<Evaluation>>

<Measurement of Light Transmittance>

The light transmittance was measured in the same manner as in Example 1.

The measurement results are presented in Table 3. Incidentally, the light transmittance of the organic EL device 201 is presented as a relative value with respect to the light transmittance of the organic EL device 101 taken as 100.

<Storage Property>

The light transmittance of each of the fabricated organic EL devices after being left to stand still for 100 hours in an environment of 60° C. and a relative humidity of 90% was measured, and the rate of change (%) in light transmittance before and after the storage property test was calculated according to the following equation.

The evaluation results are presented in Table 3.

Rate of change in light transmittance (%)=(light transmittance after storage/light transmittance before storage)×100

TABLE 3

| | | First optical adjustment layer | | | Second optical adjustment layer | | |
|---|---|---|---|---|---|---|---|
| Organic EL | Transparent | | Thickness | Refractive | | Thickness | Refractive |
| device No. | electrode | Material | [nm] | index | Material | [nm] | index |
| 103 | Al (0.6 nm)/Ag | Anthracene | 45 | 1.7 | MgF₂ | 120 | 1.3 |
| | (8 nm) | | | | | | |
| 201 | Al (0.6 nm)/Ag | Anthracene | 45 | 1.7 | MgF₂ | 120 | 1.3 |
| | (8 nm) | | | | | | |

| | | | | | Difference in | | |
|---|---|---|---|---|---|---|---|
| | | | | Light | light | | |
| | Sealing film | | | transmittance | transmittance | Storage | |
| Organic EL | | Thickness | Refractive | (relative | (visual | property | |
| device No. | Material | [nm] | index | value) | evaluation) | [%] | Remark |
| 103 | — | — | — | 110 | B | 82 | Present |
| | | | | | | | invention |
| 201 | SiON | 300 | 1.7 | 110 | B | 90 | Present |
| | film | | | | | | invention |

As is apparent from Table 3, it has been demonstrated that the organic EL device 201 exhibited a smaller rate of change in light transmittance before and after the storage property test as compared to the organic EL device 103.

From the above, it is understood that the fact that a sealing film is provided between the second optical adjustment layer and the adhesive and the sealing film is provided to be in direct contact with both the second optical adjustment layer, and the adhesive is useful to provide an organic EL device exhibiting excellent storage property.

### Example 3

<<Fabrication of Organic EL Device>>

<Fabrication of Organic EL Devices 301 to 303>

Organic EL devices 301 to 303 were fabricated in the same manner as in the fabrication of the organic EL device 201 of Example 2 except that the material of the first optical adjustment layer was changed as described in Table 4.

The method of forming the optical adjustment layer using each of the materials described in Table 4 is as follows.

Nitrogen-containing compounds 1 to 3: heated and vapor deposited at a deposition rate of about 0.1 nm/sec.

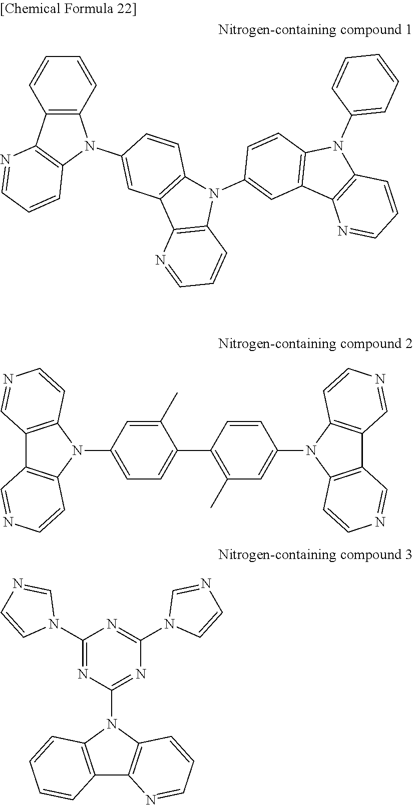 [SMILES: c1ccc(-n2c3ccc(-n4c5ccc(-n6c7ccccc7c7ncccc76)cc5c5ncccc54)cc3c3ncccc32)cc1 ; Cc1cc(-n2c3ccncc3c3cnccc32)ccc1-c1ccc(-n2c3ccncc3c3cnccc32)cc1C ; c1ccc2c(c1)c1ncccc1n2-c1nc(-n2ccnc2)nc(-n2ccnc2)n1]

<<Evaluation>>

The light transmittance and storage property were evaluated in the same manner as in Example 1 and Example 2.

The evaluation results are presented in Table 4. Incidentally, the light transmittance of the organic EL devices 301 to 303 is presented as a relative value with respect to the light transmittance of the organic EL device 101 taken as 100.

TABLE 4

| | | | | | Second optical adjustment | | |
|---|---|---|---|---|---|---|---|
| Organic | | First optical adjustment layer | | | layer | | |
| EL device | Transparent | | Thickness | Refractive | | Thickness | Refractive |
| No. | electrode | Material | [nm] | index | Material | [nm] | index |
| 201 | Al (0.6 nm)/Ag | Anthracene | 45 | 1.7 | MgF₂ | 120 | 1.3 |
| | (8 nm) | | | | | | |
| 301 | Al (0.6 nm)/Ag | Nitrogen-containing | 45 | 1.7 | MgF₂ | 120 | 1.3 |
| | (8 nm) | compound 1 | | | | | |
| 302 | Al (0.6 nm)/Ag | Nitrogen-containing | 45 | 1.7 | MgF₂ | 120 | 1.3 |
| | (8 nm) | compound 2 | | | | | |
| 303 | Al (0.6 nm)/Ag | Nitrogen-containing | 45 | 1.7 | MgF₂ | 120 | 1.3 |
| | (8 nm) | compound 3 | | | | | |

| | | | | | Difference in | | |
|---|---|---|---|---|---|---|---|
| | | | | Light | light | | |
| Organic | Sealing film | | | transmittance | transmittance | Storage | |
| EL device | | Thickness | Refractive | (relative | (visual | property | |
| No. | Material | [nm] | index | value) | evaluation) | [%] | Remark |
| 201 | SiON | 300 | 1.7 | 110 | B | 91 | Present |
| | film | | | | | | invention |
| 301 | SiON | 300 | 1.7 | 110 | B | 92 | Present |
| | film | | | | | | invention |
| 302 | SiON | 300 | 1.7 | 110 | B | 93 | Present |
| | film | | | | | | invention |
| 303 | SiON | 300 | 1.7 | 110 | B | 94 | Present |
| | film | | | | | | invention |

As is apparent from Table 4, it has been demonstrated that the organic EL devices 301 to 303 exhibited a smaller rate of change in light transmittance before and after the storage property test as compared to the organic EL device 201.

From the above, it is understood that the fact that the nitrogen-containing compound is contained in the first optical adjustment layer is useful to provide an organic EL device exhibiting excellent storage property.

### Example 4

<<Fabrication of Organic EL Device>>

<Fabrication of Organic EL Devices 401 and 402>

Organic EL devices 401 and 402 were fabricated in the same manner as in the fabrication of the organic EL device 302 of Example 3 except that lithium (thickness: 1.5 nm) and calcium (thickness: 1.5 nm) were vapor deposited between the electron injecting layer and the cathode instead of aluminum (thickness: 0.6 nm).

<<Evaluation>>

The light transmittance and storage property were evaluated in the same manner as in Example 1 and Example 2.

The evaluation results are presented in Table 5. Incidentally, the light transmittance of the organic EL devices 401 and 402 is presented as a relative value with respect to the light transmittance of the organic EL device 101 taken as 100.

TABLE 5

| | | | | | Second optical adjustment | | |
|---|---|---|---|---|---|---|---|
| Organic | | First optical adjustment layer | | | layer | | |
| EL device | Transparent | | Thickness | Refractive | | Thickness | Refractive |
| No. | electrode | Material | [nm] | index | Material | [nm] | index |
| 302 | Al (0.6 nm)/Ag | Nitrogen-containing | 45 | 1.7 | MgF₂ | 120 | 1.3 |
| | (8 nm) | compound 2 | | | | | |
| 401 | Li (1.5 nm)/Ag | Nitrogen-containing | 45 | 1.7 | MgF₂ | 120 | 1.3 |
| | (8 nm) | compound 2 | | | | | |
| 402 | Ca (1.5 nm)/ | Nitrogen-containing | 45 | 1.7 | MgF₂ | 120 | 1.3 |
| | Ag (8 nm) | compound 2 | | | | | |

| | | | | | Difference in | | |
|---|---|---|---|---|---|---|---|
| | | | | Light | light | | |
| Organic | Sealing film | | | transmittance | transmittance | Storage | |
| EL device | | Thickness | Refractive | (relative | (visual | property | |
| No. | Material | [nm] | index | value) | evaluation) | [%] | Remark |
| 302 | SiON | 300 | 1.7 | 110 | B | 93 | Present |
| | film | | | | | | invention |
| 401 | SiON | 300 | 1.7 | 112 | B | 93 | Present |
| | film | | | | | | invention |
| 402 | SiON | 300 | 1.7 | 113 | B | 93 | Present |
| | film | | | | | | invention |

As is apparent from Table 5, it has been demonstrated that the organic EL devices 401 and 402 have a higher light transmittance and a smaller light transmittance ratio between the light emitting region and the non-light emitting region as compared to the organic EL device 302.

From the above, it is understood that the fact that a layer composed of Li or Ca between is provided the electron injecting layer and the cathode is useful to provide an organic EL device having a high light transmittance.

### INDUSTRIAL APPLICABILITY

The present invention can be particularly suitably utilized to provide an organic EL device having a high light transmittance and a small difference in light transmittance between a light emitting region and a non-light emitting region.

### REFERENCE SIGNS LIST

1: Organic EL device
2: Supporting substrate
4: Lower transparent electrode
4a: Power supply portion
6: Organic functional layer
8: Upper transparent electrode
8a: Power supply portion
10: First optical adjustment layer
12: Second optical adjustment layer
14: Laminated body
16: Adhesive
18: Sealing substrate
20: Sealing film
100: Vacuum ultraviolet irradiation apparatus
102: Chamber
104: Stage
106: Shielding plate
108: Xe excimer lamp
110: Holder
L: Light emitting region
NL: Non-light emitting region

1. An organic electroluminescence device comprising:
a laminated body having at least a lower transparent electrode, an organic functional layer including a light emitting layer, an upper transparent electrode, a first optical adjustment layer, and a second optical adjustment layer laminated on a supporting substrate in this order; and
a sealing substrate pasted to the supporting substrate via an adhesive so as to cover a light emitting region of the light emitting layer; wherein
a refractive index of the first optical adjustment layer is greater than a refractive index of the second optical adjustment layer, and
the upper transparent electrode and the first optical adjustment layer, and the first optical adjustment layer and the second optical adjustment layer are provided to be in direct contact with each other, respectively.

2. The organic electroluminescence device according to claim 1, wherein
a sealing film is provided between the second optical adjustment layer and the adhesive, and
the sealing film is provided to be in direct contact with both the second optical adjustment layer and the adhesive.

3. The organic electroluminescence device according to claim 1, wherein the upper transparent electrode is a metal thin film.

4. The organic electroluminescence device according to claim 1, wherein a nitrogen-containing compound is contained in the first optical adjustment layer.

5. A lighting apparatus comprising the organic electroluminescence device according to claim 1.

6. The organic electroluminescence device according to claim 2, wherein the upper transparent electrode is a metal thin film.

7. The organic electroluminescence device according to claim 2, wherein a nitrogen-containing compound is contained in the first optical adjustment layer.

8. A lighting apparatus comprising the organic electroluminescence device according to claim 2.

9. The organic electroluminescence device according to claim 3, wherein a nitrogen-containing compound is contained in the first optical adjustment layer.

10. A lighting apparatus comprising the organic electroluminescence device according to claim 3.

11. A lighting apparatus comprising the organic electroluminescence device according to claim 4.
